(19) United States
(12) Patent Application Publication
(10) Pub. No.: US 2006/0068173 A1
(43) Pub. Date: Mar. 30, 2006

(54) Methods for forming and patterning of metallic films

(75) Inventors: Masaaki Kajiyama, Zushi-shi (JP); Osamu Horita, Kawasaki-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EBARA CORPORATION, Tokyo (JP)

(21) Appl. No.: 11/113,244

(22) Filed: Apr. 25, 2005

(30) Foreign Application Priority Data
Sep. 30, 2004 (JP) 2004-286846
Mar. 9, 2005 (JP) 2005-065302
Mar. 9, 2005 (JP) 2005-065308

(51) Int. Cl. B32B 15/04; B41M 5/00; B05D 1/36; B05D 1/18; C23C 16/00; B05B 5/025; B21D 39/00

(52) U.S. Cl. 428/195.1; 428/457; 428/624; 427/402; 427/443.1; 118/620; 118/719

(57) ABSTRACT

A solvent containing an organic or inorganic metal compound containing a metal catalyst that serves as a plating seed is applied to a plastic substrate and dried, thereby forming a metal compound film, and then, the metal compound film is irradiated with an energy beam, such as an electron beam, to precipitate the metal catalyst. By irradiating a local area of the metal compound film with the energy beam, the chemical reaction of metal catalyst precipitation can be caused locally in the irradiated area, and thus, a patterned metal catalyst film can be formed. Once the substrate is irradiated with the energy beam, the surface may be molten to trap the metal catalyst to an extremely shallow depth, so that the bonding between the substrate and the metal catalyst is enhanced. Thus, the metal catalyst film becomes harder to peel off the substrate.

### BACKGROUND OF THE INVENTION

1. Field of the Invention

The present invention relates to a substrate having an insulating layer and a metallic film formed thereon, such as a printed circuit board and a silicon wafer, and a method of fabricating the same. More particularly, it relates to a technique of patterning or printing a metal catalyst film, which constitutes a seed for forming a metal plating layer, on an insulating layer of a printed circuit board or silicon wafer and plating the metal catalyst film.

2. Description of the Related Art

Printed circuit boards, which are referred to also as printed wiring boards and fabricated by forming a conductive wiring pattern on an insulating substrate by plating or the like, provide a basis for circuit implementation.

As methods of forming a circuit pattern on such a printed circuit board, for example, there are known an etching method using a photosensitive resist, a subtractive method involving plating a substrate with copper and removing the unwanted portions of the copper plating by etching, a full-additive method involving electrolessly plating a catalyst-containing substrate according to a desired pattern, and a semi-additive method involving electrolessly plating a catalyst-containing substrate according to a desired pattern and electroplating the resulting pattern.

For example, Japanese Patent Laid-Open No. 7-50470 discloses a printed circuit board with a high-density wiring pattern and a method of fabricating the same, and this technique makes the most of the advantage of the electroless solder plating that it can form a uniform film. The technique is described as capable of solving the problem with the prior art that the processing accuracy of circuit patterns is 100 to 120 μm in line width at most, and the wiring cannot be narrower than these values.

Furthermore, Japanese Patent Laid-Open Nos. 2002-76573 and 2002-76574 disclose a method of fabricating a printed circuit board including a step of depositing a metal catalyst, such as palladium, in the shape of a wiring pattern in a circuit pattern area and a step of forming a metal wiring pattern by plating the wiring-patterned metal catalyst with a metal. In addition, in “Effects of Substrate Material and Palladium Acetate Film Thickness on Laser Writing of Palladium Patterns”, by Eiji Makino et al., Journal of Surface Finishing, No. 49, Vol. 9 (1998), pages 90-95 together with English translation thereof, there is a report about effects of a substrate material and a palladium acetate film thickness on laser writing of a palladium pattern.

However, these conventional fabrication processes for a printed circuit board all requires a series of steps including application of a photoresist, lamination of a photosensitive dry film resist, and stripping of the photoresist and the photosensitive dry film resist for patterning the plating wiring. Thus, there is a problem that the fabrication processes are complicated.

Such a complication problem is not limited to the fabrication processes for a printed circuit board, but is found in a process of patterning a metal film on a silicon wafer, for example.

In Japanese Patent Laid-Open No. 57-139923, there is disclosed a technique of patterning a metal film by irradiating a silver halide film with an electron beam, x-rays or an ion beam to directly pattern the silver halide film and electrolessly plating the patterned silver halide film with a metal by the action of the catalytic action of silver, without using a resist of a polymeric material that is limited in sensitivity.

However, the study by the inventors has proved that the metal film patterned by the patterning method described in Japanese Patent Laid-Open No. 57-139923 is inferior in adhesion to the substrate, and the plating wiring on the printed circuit board patterned by this method cannot have a practically sufficient adhesion and is easy to come off. In other words, while the patterning method described in Japanese Patent Laid-Open No. 57-139923 has an advantage that it can achieve highly sensitive patterning without using a resist, the resulting metal pattern does not adequately adhere to the substrate, and therefore, it is difficult to assure a high production yield of electronic components.

In addition, in the Commentary of “Paste containing metal nanoparticles at high concentration”, by Hideo Ishibashi, Chemistry and Chemical industry No. 9, Vol. 57 (2004), pages 945-947 together with English translation thereof, there is a report about a technique of forming a circuit pattern that involves ink-jet printing a circuit using a metal nanoparticle paste and then sintering the printed circuit, thereby forming a conductive metal thin film or thin line. However, since the variety of metal elements that can be made into nanoparticles is limited, such a patterning technique has a problem that it is limited in application compared with a metal film patterning technique relying on plating. In addition, there is a problem that, even if the metal element used is included in the limited variety of metal elements, if the sintering temperature is low, the electric resistance of the resulting pattern cannot be reduced adequately.

### SUMMARY OF THE INVENTION

The present invention has been devised in view of such circumstances, and an object of the present invention is to provide a wiring plating method that does not need the steps of application of a resist, lamination of a photosensitive dry film resist, exposure, etching of a copper foil and stripping of the photosensitive material that are essential for the conventional techniques to form a patterned plating wiring on a substrate, such as a printed circuit board, and assures sufficient adhesion of the obtained plating wiring to the substrate, thereby providing a technique that enables simplification of the manufacturing process and reduction of the manufacturing cost.

The present invention has a first aspect intended for patterning of a metal film, which serves as a plating catalyst for a metal wiring, by energy beam irradiation and a second aspect intended for patterning of a metal film by printing using an ink jet printer or the like.

According to the first aspect of the present invention, there is provided a substrate having a metal film, comprising: a patterned metal catalyst film formed on an insulating layer formed on a flat plate or a principal surface of an insulating flat base material; and a metal wiring formed by plating on the metal catalyst film, in which the insulating layer and the insulating flat base material are made of a plastic resin that can be molten, ablated or chemically modified locally in an area that is irradiated with an energy beam.

Preferably, the plastic resin is a resin selected from a group containing polyimide, epoxy, bismaleimide triazine (BT resin), polyphenylene ether, polyacetal and phenol or a fiber reinforced plastic resin that contains a resin selected from the group.

According to another implementation of the first aspect of the present invention, there is provided a substrate having a metal film, comprising: a patterned metal catalyst film formed on an insulating layer formed on a flat plate or a principal surface of an insulating flat base material; and a metal wiring formed by plating on the metal catalyst film, in which the metal compound or granular metal in the metal catalyst film serving as the plating catalyst for metal wiring is dispersed or mixed in at least one of a liquid binder and a granular binder that are the same material as or highly compatible with the insulating layer or insulating flat base material and can be made adhesive to a surface of the insulating layer or insulating flat base material by irradiation with an energy beam.

The average diameter of the granular binder is preferably equal to or more than 0.1 μm and equal to or less than 10 μm, more preferably equal to or more than 0.1 μm and equal to or less than 5 μm, or further preferably equal to or more than 0.1 μm and equal to or less than 1 μm.

According to the first aspect, the metal catalyst film may be a film containing at least one compound selected from a group containing a metal carboxylate, a nitrate compound, a chloride, an iodine compound, a hydroxide, a fluorine compound, a sulfate compound, a sulfur compound, and a compound of a chelate compound and an organic compound.

In addition, the metal compound or granular metal may be a metal selected from a group containing Pd, Au, Pt, Ag, In, Co and Sn or an alloy of at least two metals selected from the group.

Preferably, an adhesive made of a material that is the same as or highly compatible with the material of the insulating layer or insulating flat base material is provided on a surface of the insulating layer or insulating flat base material. The thickness of the applied adhesive is preferably equal to or more than 0.05 μm and equal to or less than 10 μm.

Such a substrate according to the first aspect of the present invention can be fabricated by a method of forming a metal film, comprising: a first step of forming a film containing a metal compound containing a first metal on an insulating layer formed on a flat plate or a principal surface of an insulating flat base material by applying a metal compound film containing the first metal to the insulating layer or the principal surface of the insulating flat base material; a second step of irradiating the film containing the metal compound containing the first metal with an energy beam, thereby precipitating the first metal from the film containing the metal compound containing the first metal and locally melting, ablating or chemically modifying the area of the insulating layer or the insulating flat base material that is irradiated with the energy beam; and a third step of, using the precipitated first metal as a catalyst layer, plating the surface of the catalyst layer with a second metal using a plating solution containing the second metal, thereby forming a second metal film.

Alternatively, the substrate according to the first aspect of the present invention can be fabricated by a method of forming a metal film, comprising: a first step of forming a film containing a metal compound containing a first metal on an insulating layer formed on a flat plate or a principal surface of an insulating flat base material by applying a metal compound film containing the first metal to the insulating layer or the principal surface of the insulating flat base material; a second step of irradiating the film containing the metal compound containing the first metal with an energy beam, thereby precipitating the first metal from the film containing the metal compound containing the first metal; and a third step of, using the precipitated first metal as a catalyst layer, plating the surface of the catalyst layer with a second metal using a plating solution containing the second metal, thereby forming a second metal film, in which the metal compound containing the first metal forming the film is a metal compound or granular metal for serving as a plating catalyst for the second metal that is dispersed or mixed in at least one of a liquid binder and a granular binder that are the same material as or highly compatible with the insulating layer or insulating flat base material, and the energy beam irradiation in the second step is performed under a condition that the binder is physically or chemically changed to adhere the surface of the insulating layer or insulating flat base material.

Preferably, these methods further comprise a step of applying an adhesive made of a material that is the same as or highly compatible with the insulating layer or insulating flat base material to the insulating layer or the principal surface of the insulating flat base material before the first step, and the first step is performed after the applied adhesive is cured or partially cured.

In these methods, preferably, the energy beam is selected from among an electron beam, a microwave, an ion beam, infrared rays, ultraviolet rays, vacuum ultraviolet rays, an atomic beam, X-rays, γ-rays, visible light and a laser beam.

In addition, the energy beam irradiation can be performed by scanning the insulating layer on the flat plate or the principal surface of the insulating flat base material with the energy beam or by using a mask that allows the energy beam to be incident only on the area corresponding to the desired pattern to be formed.

Furthermore, preferably, the second step may include a sub-step of removing the film containing the metal compound containing the first metal in the area that is not irradiated with the energy beam after the irradiation with the energy beam or a sub-step of performing a heat treatment after the first metal is precipitated.

According to the first aspect of the present invention, in fabrication of a printed circuit board, for example, the metal film serving as a catalyst for metal wiring plating is directly patterned on the printed circuit board by irradiating the metal film with an energy beam, such as an electron beam, thereby plating only the metal catalyst film with the wiring-forming metal, and substrate surface is molten or the binder is modified by the electron beam irradiation. Thus, the obtained plating wiring has a sufficient adhesion to the substrate. Such a wiring plating method does not require resist application and stripping in the patterning step of the plating wiring, and thus, the manufacturing process of the printed circuit board is simplified.

The second aspect of the present invention also relates to a technique of fabricating a substrate. According to the second aspect, there is provided a method of patterning a metal film, comprising: a first step of printing a desired pattern of a metal compound film containing a first metal on an insulating layer or principal surface of an insulating base material, thereby forming a film containing the metal compound containing the first metal on the principal surface of the insulating base material; a second step of irradiating the film containing the metal compound containing the first metal with an energy beam, thereby precipitating the first metal from the film containing the metal compound containing the first metal and locally melting, ablating or chemically modifying the area of the insulating base material that is irradiated with the energy beam; and a third step of, using the precipitated first metal as a catalyst, plating the surface of the catalyst layer with a second metal.

Furthermore, there is provided a method of patterning a metal film, comprising: a first step of printing a desired pattern of a metal compound film containing a first metal on an insulating layer or principal surface of an insulating base material, thereby forming a film containing the metal compound containing the first metal on the principal surface of the insulating base material; a second step of externally energizing the film containing the metal compound containing the first metal, thereby precipitating the first metal from the film containing the metal compound containing the first metal; and a third step of, using the precipitated first metal as a catalyst layer, plating the surface of the catalyst layer with a second metal, in which the metal compound containing the first metal forming the film is a metal compound or granular metal for serving as a plating catalyst for the second metal that is dispersed or mixed in at least one of a liquid binder and a granular binder that are the same material as or highly compatible with the insulating flat base material, and the external energization in the second step is energy beam irradiation or heat treatment performed under a condition that the binder is physically or chemically changed to adhere the surface of the insulating base material.

Preferably, the pattern printing of the metal compound in the first step is performed by laser shot printing using a powder of the first metal or ink jet printing or micro-contact printing using a solvent containing the metal compound containing the first metal as an ink material.

In addition, preferably, the solvent contains at least one of a liquid binder and a granular binder that are the same material as or highly compatible with the insulating layer or insulating base material.

In addition, preferably, the powder is mixed with or contains a granular binder that is the same material as or highly compatible with the insulating layer or insulating base material.

In these methods, preferably, the energy beam is selected from among an electron beam, a microwave, an ion beam, infrared rays, ultraviolet rays, vacuum ultraviolet rays, an atomic beam, X-rays, γ-rays, visible light and a laser beam.

According to the second aspect, in fabricating a printed circuit board, for example, the metal catalyst film that serves as a catalyst for metal wiring plating is printed on the surface of the insulating printed circuit board by an ink jet printer or the like, and then, the film is irradiated with an energy beam, such as an electron beam, or externally heated to precipitate the metal catalyst, and only the precipitated metal catalyst film is plated with the wiring-forming metal. In addition, the substrate surface is molten or the binder is modified by external energization, and therefore, the obtained plating wiring has a sufficient adhesion to the substrate. In addition, such a wiring plating method does not require the steps of resist application, exposure, etching and resist stripping for patterning the plating wiring, and therefore, the manufacturing process of the printed circuit board is simplified.

By applying the present invention to a manufacturing process of a printed circuit board, it is possible to reduce the manufacturing cost of the printed circuit board for mounting electronic components that is incorporated into an information device, such as a cellular phone, which is desired to have a smaller size and a higher performance. In addition, since the metal catalyst film formed in the present invention serves as a catalyst for plating, the amount thereof is extremely small compared with the plating metal to serve as a conductor (copper, for example). Thus, it is possible to reduce the manufacturing cost of the printed circuit board for mounting electronic components that is incorporated into an information device, such as a cellular phone, which is desired to have a smaller size and a higher performance.

For example, a substrate fabricating apparatus according to the present invention comprises: a carrier unit that has a holding table for holding a flat plate and an arm for carrying the flat plate; an applying unit that applies a metal compound containing a first metal to an insulating layer on the flat plate; an energy beam irradiation unit that irradiates the applied metal compound containing the first metal with an energy beam in a predetermined pattern; a washing unit that washes the surface of the insulating layer on the flat plate irradiated with the energy beam; a metal plating unit that plates the washed insulating layer on the flat plate with a second metal; an insulating film applying unit that applies an insulating film on the flat plate; an insulating film curing unit that cures the insulating film; and a hole forming unit that forms at least one of a via hole and a through hole, in which the carrier unit is controlled by a controller so as to sequentially carry the flat plate from the applying unit to the energy beam irradiation unit, from the energy beam irradiation unit to the washing unit, from the washing unit to the metal plating unit, from the metal plating unit to the insulating film applying unit, from the insulating film applying unit to the insulating film curing unit, and from the insulating film curing unit to the hole forming unit.

Preferably, the substrate fabricating apparatus is connected to a host computer via a network, and the host computer can collectively manage the substrate fabricating process.

### BRIEF DESCRIPTION OF THE DRAWINGS

FIGS. 1A to 1F are diagrams for illustrating a first part of a method of fabricating a printed circuit board according to a first aspect of the present invention;

FIGS. 2A to 2F are diagrams for illustrating a second part of the method of fabricating a printed circuit board according to the first aspect of the present invention;

FIGS. 3A to 3E are diagrams for illustrating a third part of the method of fabricating a printed circuit board according to the first aspect of the present invention;

FIG. 4 is a conceptual diagram for illustrating a configuration of a patterning apparatus for fabricating a printed circuit board according to the first aspect of the present invention;

FIG. 5 is a conceptual diagram for illustrating a configuration of the patterning apparatus according to the first aspect of the present invention;

FIG. 6 is a diagram for illustrating a process of carrying a substrate introduced into the patterning apparatus through a substrate inlet thereof;

FIG. 7A is a schematic diagram for illustrating a configuration of an electron beam irradiation unit of a scan-writing type;

FIG. 7B is a schematic diagram for illustrating a configuration of an electron beam irradiation unit of a mask type;

FIG. 7C is a side view of the electron beam irradiation unit of the mask type shown in FIG. 7B for illustrating a configuration of an electron beam irradiation system thereof;

FIG. 8 is a diagram for illustrating a process of carrying the substrate having been irradiated with the electron beam to a second washing tank;

FIG. 9 is a diagram for illustrating a process of forming a wiring pattern by plating;

FIG. 10 is a diagram for illustrating processes of drying the substrate, curing an insulating film, planarizing the film, forming a via hole or through hole and drilling a hole;

FIG. 11 is a diagram for illustrating a process following the drying of the substrate and preceding the exit of the substrate through an outlet;

FIGS. 12A to 12E are optical microscope photographs for illustrating a pattern of a line width of 12 μm formed by electron beam irradiation using a mask and electroless plating, in which FIG. 12A shows a mask pattern, FIG. 12B shows a resulting plating pattern, FIG. 12C shows a pattern of a line width of 25 μm, and FIGS. 12D and 12E show a pattern of a line width of 12 μM;

FIGS. 13A to 13F are diagrams for illustrating a first part of a method of fabricating a printed circuit board according to a second aspect of the present invention;

FIGS. 14A to 14F are diagrams for illustrating a second part of the method of fabricating a printed circuit board according to the second aspect of the present invention;

FIGS. 15A to 15E are diagrams for illustrating a third part of the method of fabricating a printed circuit board according to the second aspect of the present invention;

FIG. 16 is a conceptual diagram for illustrating a configuration of a patterning apparatus according to the second aspect of the present invention;

FIG. 17 is a diagram for illustrating a process of carrying a substrate introduced into the patterning apparatus through a substrate inlet thereof;

FIG. 18A is a schematic diagram for illustrating configurations of an electron beam irradiation unit and a heating unit;

FIG. 18B is a side view of the electron beam irradiation unit shown in FIG. 18A for illustrating a configuration of an electron beam irradiation system thereof;

FIG. 19 is a diagram for illustrating a process of carrying the substrate from a first pre-plating treatment unit to an electroless-plating unit;

FIG. 20 is a diagram for illustrating a process of forming a wiring pattern by plating;

FIG. 21 is a diagram for illustrating processes of drying the substrate, curing an insulating film, planarizing the film, forming a via hole or through hole and drilling a hole; and

FIG. 22 is a diagram for illustrating a process following the drying of the substrate and preceding the exit of the substrate through an outlet.

### DETAILED DESCRIPTION OF THE PREFERRED EMBODIMENTS

In the following, with reference to the drawings, a substrate according to the present invention and a method of fabricating the same according to the present invention will be described.

(First Aspect: Patterning Using Irradiation with Energy Beam)

In the following, a printed circuit board and a method of fabricating the same according to a first aspect of the present invention will be described. It is noted that the present invention is not limited to the printed circuit board, but can be applied to any wiring on an insulating film (an insulating layer) formed on a semiconductor substrate, such as a silicon wafer. Unless otherwise specified, the term “substrate”, “base material” or the like used herein means not only a printed circuit board and a semiconductor substrate with an insulating film formed thereon, but also a common substrate or base material whose base on which a metal film is formed is an insulator. Furthermore, the phrase “an insulating film (an insulating layer) on a substrate (a flat plate)” used herein may mean not only an insulating film (an insulating layer) formed on a semiconductor substrate, such as a silicon wafer, but also an insulating flat plate itself of a printed circuit board.

An example of a method of fabricating a substrate according to the present invention is a method of fabricating a printed circuit board. In this case, before electro-plating or electroless-plating the printed circuit board with a metal for forming wiring, a metal that functions as a “plating catalyst” for the wiring-forming metal is patterned. Then, using the metal catalyst film patterned on the printed circuit board as a seed for metal plating, a wiring pattern is formed so that only the metal catalyst film is plated with the wiring-forming metal. In other words, patterning is achieved because a second metal film of a plating metal, which is a second metal, is formed only on a film containing a catalyst metal, which is a first metal.

To precipitate the metal catalyst, a film of an organic metal compound or inorganic metal compound containing a metal serving as a plating catalyst is formed on a base material (printed circuit board), and the film is locally irradiated with an energy beam, such as an electron beam. Such local irradiation with an energy beam can impart energy only to the metal compound in the irradiated area, and the chemical reaction of precipitation of the metal catalyst occurs only in that area. Thus, it is possible to locally precipitate the metal catalyst.

Unless otherwise specified, the term “metal compound” used in the following description means an organic metal compounds or inorganic metal compound. In addition, the term “metal compound” may also mean a metal complex. Furthermore, the term “printed circuit board” means not only a substrate with a metal wiring formed thereon, but also a substrate that is yet to be mounted with a metal wiring (that is, a base material).

The precipitation of the metal catalyst from the metal compound in the area irradiated with an energy beam according to the present invention is advantageous in that the series of steps of application, exposure and stripping of a photoresist, which are necessary in conventional patterning processes, can be omitted and that the temperature rise or heat diffusion to areas close to the irradiated area caused by the heat generated by the precipitation can be reduced significantly. Thus, it is possible to impart the energy required to precipitate the metal catalyst only to the metal compound film in the area to be patterned and, therefore, to control the area for metal catalyst precipitation quite accurately. Thus, according to the present invention, it is possible to precipitate the metal catalyst within a spatial range substantially equal to the diameter of the scanning irradiating energy beam or the size of a hole in the mask used for patterning of the metal compound film.

In general, in the case of precipitating a metal catalyst through thermal decomposition of a metal compound, the substrate has to be heated to a relatively high temperature in order to supply thermal energy enough to achieve precipitation. However, if the substrate is kept at such a high temperature, the metal catalyst precipitated on the substrate is crystallized rapidly, the crystal particles grow rapidly, and the precipitated metal particles become too large. Thus, it is difficult to enhance the linkage among metal particles to form a continuous film.

On the other hand, according to the energy beam irradiation method used in the present invention, the energy required to precipitate the metal catalyst can be supplied locally with the substrate being kept at a low temperature. Thus, the metal catalyst can be precipitated on the substrate as amorphous fine particles of a uniform size uniformly distributed, and the metal catalyst film in which the crystal particles are firmly linked together can be formed.

Following the film formation, a post-film-formation heat treatment may be conducted to crystallize or sinter the metal catalyst film, and the temperature of the heat treatment may be appropriately determined according to the object of the treatment, the kind of the metal catalyst or the base material being used. Such a post-film-formation heat treatment not only achieves crystallization or sintering of the metal catalyst film but also provides an advantage that the concentration of carbon or oxygen in the film, which is an impurity that is trapped in the film and increases the resistance of the film, is reduced. To reduce the amount of carbon or oxygen in the film, it is effective to heat-treat the film in an atmosphere containing hydrogen.

Here, the metal used as the plating catalyst is appropriately chosen according to the kind of the wiring-forming metal (copper (Cu), for example) and may be palladium (Pd), gold (Au), platinum (Pt), silver (Ag), indium (In), cobalt (Co) or tin (Sn), for example. In addition, the catalyst may be one of these metals or an alloy of two or more metals selected from among these metals.

The metal compound containing such a catalyst metal may be a metal carboxylate, a nitrate compound, a chloride, an iodine compound, a hydroxide, a fluorine compound, a sulfate compound or a compound of a chelate compound and an organic compound, or a metal compound composed of two or more of the above-described compounds. For example, the metal compound may be palladium acetate, tetraamine palladium acetate, indium acetate or indium 2-ethylhexanoate as an organic metal compound, or palladium chloride, palladium nitrate or indium chloride as an inorganic metal compound.

In the formation of a film of a metal compound containing a metal catalyst on a substrate, it is important to form the film of a uniform thickness on the substrate. This is because, if the film thickness is not uniform, the density of the energy imparted by the energy beam varies with the place, and the extent of precipitation of the metal catalyst varies with the place, and because, if the film formation varies with the place on the substrate, a break or the like occurs in the final metal wiring pattern. To achieve such uniform film formation, it is preferred that the substrate is spin-coated with a solvent containing a metal compound.

The solvent for the metal compound depends on the kind of the organic metal compound or inorganic metal compound used as the metal catalyst material and may be water, a hydrocarbon solvent, such as alcohol, ketone, acetone and toluene, or an acid solvent. The amount of the metal compound dissolved in the solvent and the condition for spin-coating are determined so that the thickness of the final metal compound film resulting from drying the applied solvent with a hot plate or the like is equal to or more than 0.1 μm and equal to or less than 0.5 μm, preferably so that the thickness is equal to or more than 0.2 μm and equal to or less than 0.5 μm, or more preferably so that the thickness is equal to or more than 0.3 μm and equal to or less than 0.5 μm.

Such determination of the film thickness is intended to assure the continuity of the metal catalyst film in the irradiated area even if the irradiating energy beam induces a chemical reaction of the organic metal compound or inorganic metal compound, and the volume thereof shrinks when the metal catalyst is precipitated. Specifically, if the metal compound film after the solvent is dried is too thin, the metal catalyst may be nonuniformly precipitated in the area irradiated with the energy beam. If such nonuniform precipitation occurs, a defect, such as a pin hole, may occur in the metal catalyst film serving as a plating seed and inhibit uniform plating of the predetermined area to be patterned with the metal wiring. To surely avoid such a problem, the thickness of the metal compound film is preferably equal to or more than 0.3 μm. Furthermore, to prevent the adhesion between the metal compound film and the substrate from being reduced, the thickness is preferably equal to or less than 0.5 μm.

The base material of the printed circuit board is an insulating flat plate, and materials whose surface can be chemically modified, molten or ablated by energy beam irradiation locally in the irradiated area are preferably used. This is intended to make the metal catalyst precipitated by irradiation with the energy beam adhere to the substrate with reliability.

Specifically, the substrate surface may be molten to trap the metal catalyst in the substrate to an extremely shallow depth, or the substrate surface may be ablated to effectively increase the contact area between the metal catalyst and the substrate surface, or alternatively, the substrate surface may be chemically modified to enhance the bonding between the substrate and the metal catalyst, thereby raising the degree of adhesion therebetween. By choosing the substrate in this way, the metal catalyst film becomes hard to peel from the substrate during the subsequent plating step for forming the metal wiring.

As the material of the substrate, a plastic resin is preferably used. In the case where the base material is a plastic resin, the plastic resin may be one selected from a group consisting of polyimide, epoxy, bismaleimide triazine, polyphenylene ether, polyacetal and phenol, or may be a fiber-reinforced plastic resin based on a resin selected from the group described above.

For enhancing the adhesion of the metal catalyst film to the substrate, the metal compound or metal particles serving as the plating catalyst for the metal wiring may be effectively dispersed or mixed in a liquid binder and/or a granular binder that is the same as or highly compatible with the material of the substrate on which the metal catalyst film is to be formed. For example, a granular binder that is the same as or highly compatible with the substrate material is dispersed or dissolved in the solvent for dissolving the metal compound serving as the plating catalyst for the metal wiring, and the solvent is applied onto the substrate. In the case where such a binder is used, the metal compound film resulting from drying the solvent contains the binder that is the same as or highly compatible with the substrate material. However, irradiating the film with an energy beam can cause not only melting, physical bonding or chemical reaction in the irradiated area of the substrate surface but also melting, physical bonding or chemical reaction of the binder in the film, thereby firmly bonding the binder and the substrate surface to each other after the energy beam irradiation. Consequently, the adhesion of the metal catalyst film to the substrate can be enhanced.

For example, if polyphenylene ether is used as a binder, a granular binder is dissolved in toluene, which is a good solvent for polyphenylene ether, and an adequate amount of the toluene solution is added to the solvent containing the metal compound to form a solution to be applied.

Here, in the case where a granular binder is dispersed in the solvent, the diameter of the particles is preferably equal to or less than 10 μm and equal to or more than 0.1 μm, more preferably equal to or less than 5 μm and equal to or more than 0.1 μm, and further preferably equal to or less than 1 μm and equal to or more than 0.1 μm, considering the line width of the wiring obtained by plating and the precision of the finished surface. The material of the binder may not be the same as the substrate material but can be selected from among those that are highly compatible with the substrate material. Here, the term “compatible” means that a material is in a state where it can easily be mixed with or react with another material or a state where it can easily adhere to another material due to a significant intermolecular force.

Of course, the technique of using a binder can be used together with the technique of melting the substrate surface to make the substrate trap the metal catalyst to an extremely shallow depth, or the technique of ablating the substrate surface to effectively increase the contact area between the metal catalyst and the substrate surface, or the technique of chemically modifying the substrate surface to enhance the bonding between the substrate and the metal catalyst, thereby raising the degree of adhesion therebetween described above.

Furthermore, besides these techniques, it is effective to apply an adhesive that is the same material as or highly compatible with the substrate material to the substrate to a thickness from 0.05 to 10 μm and pattern the metal catalyst after the applied adhesive is completely or partially cured.

As for the energy beam used for precipitating the metal serving as the plating catalyst on the printed circuit board, an energy beam suitable for precipitating the metal in the metal compound selected as the metal catalyst material and patterning the precipitated metal into a desired shape is selected. For example, the energy beam may be an electron beam, a microwave, an ion beam, infrared rays, ultraviolet rays, vacuum ultraviolet rays, atomic beam, X-rays, γ-rays, visible light, or a laser beam. Furthermore, of course, the energy of the energy beam can be determined to fall within an appropriate range depending on the metal catalyst to be precipitated.

In order to obtain a printed circuit board with a fine pattern of wiring having a line width equal to or less than 30 μm, the energy beam is preferably an electron beam, an atomic beam or X-rays, which are easy to reduce the beam diameter. In the case where any of these beams is used, the beam diameter can be reduced to 5 μm or less, so that fine patterning can be achieved. In particular, the electron beam is preferred, because the beam diameter can be reduced to about 10 nm and be easily adjusted, and the scanning technique thereof is established, so that a fine pattern can be relatively easily drawn on the substrate. The fact that such a fine pattern can be drawn means that the technique can be applied to wiring of semiconductor devices.

In the case where the electron beam is used as the energy beam, the applied voltage is appropriately determined considering the intended beam diameter on the irradiation area. Typically, it is determined to fall within a range from 3 keV to 300 keV. Here, if the applied voltage is too high, the energy density per unit area of the irradiation area is also too high, which may cause excessive melting of the substrate surface, sublimation of the metal compound rather than precipitation of the metal catalyst, attacking of the electron beam only on the substrate through the film on the surface thereof, or other disadvantageous effects. Thus, the energy value of the energy beam is preferably determined to fall within a range from 3 keV to 30 keV, and more preferably to fall within a range from 3 keV to 15 keV.

When forming a metal catalyst film by irradiating a metal compound film with an energy beam in this way, the metal compound film is scanned with the energy beam in such a manner that the plating metal wiring on the metal catalyst film forms the wiring pattern on the printed circuit board, or a patterning mask is used for allowing the energy beam to be incident only on the area corresponding to the wiring pattern to be formed. If only the desired area is irradiated with the energy beam through such a technique, the catalyst metal is precipitated in the irradiated area, while the metal compound remains unreacted in the area that is not irradiated with the energy beam.

Then, when the metal compound remaining unreacted is removed with a solvent of an appropriate composition, only the patterned metal catalyst film remains on the substrate. The removal of the metal compound remaining unreacted can be conducted by ultrasonic cleaning of the entire substrate in a solvent, for example.

Then, using the patterned metal catalyst film on the substrate as a seed, only the seed is plated with a wiring-forming metal to form a wiring pattern. Of course, not only such a single-layered wiring pattern but also multi-layered wiring patterns can be formed.

In the following, a method of fabricating a printed circuit board according to a first aspect of the present invention will be described in detail with reference to embodiments thereof.

### Embodiment 1

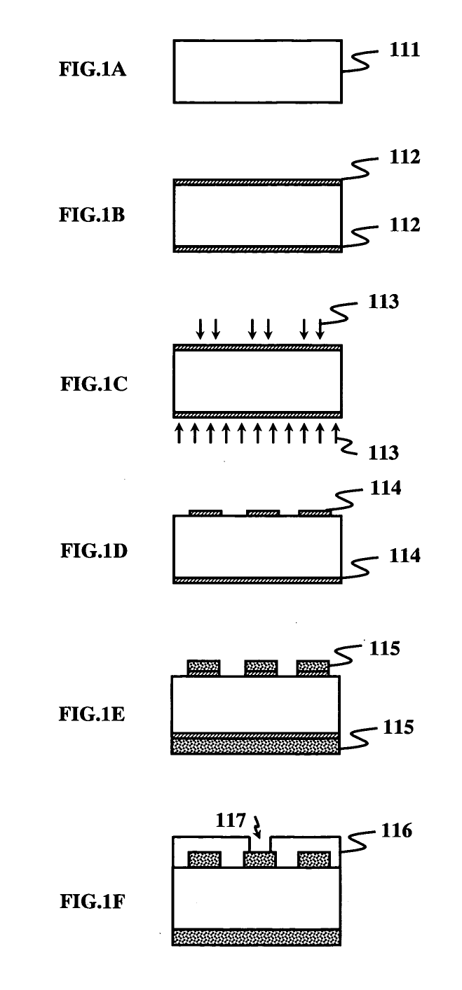

FIGS. 1A to 1F, FIGS. 2A to 2F, and FIGS. 3A to 3E are diagrams for illustrating a first example of a method of fabricating a printed circuit board according to the first aspect of the present invention, and the printed circuit board shown in these drawings for illustration has three layers of wiring pattern on one side. Here, FIGS. 1A to 1F, FIGS. 2A to 2F, and FIGS. 3A to 3E correspond to procedures of forming a wiring pattern of a first layer, a wiring pattern of a second layer and a wiring pattern of a third layer, respectively.

First, a substrate 111, which is an insulating planar substrate, is prepared (FIG. 1A), and a solvent containing an organic or inorganic metal compound containing a metal catalyst serving as a seed for plating is applied to the both principal surfaces of the substrate 111 and dried to form a metal compound film 112 (FIG. 1B). The substrate 111 used herein is a plastic substrate, which is a material whose surface area can be locally molten, ablated or chemically modified by irradiation with an energy beam in the area corresponding to the irradiation, such as polyimide, epoxy, bismaleimide triazine, polyphenylene ether, polyacetal and phenol.

In addition, palladium acetate, which is an organic metal compound, is selected as the metal compound, and Pd therein is precipitated as the metal catalyst. An acetone solvent containing the metal compound is applied uniformly to the substrate 111 by spin-coating so that the thickness of the metal compound film resulting from drying of the solvent is 0.1 μm or more, preferably 0.2 μm or more, and more preferably 0.3 μm or more.

Then, the area of the metal compound film 112 corresponding to a desired pattern is irradiated with an energy beam 113, such as an electron beam, to precipitate the metal catalyst in the irradiated area (FIG. 1C). Here, an electron beam is used as the energy beam. The diameter of the irradiating beam is reduced to the width of the desired wiring pattern, and the acceleration voltage thereof is determined within a range from 3 keV to 15 keV. As desired, a required number of irradiations can be performed.

The energy beam irradiation is performed by scanning the metal compound film with the energy beam in such a manner that the plating metal wiring on the metal catalyst film forms the wiring pattern on the printed circuit board, or using a patterning mask for allowing the energy beam to be incident only on the area corresponding to the wiring pattern to be formed. An energy beam irradiating apparatus used therefor will be described later.

In addition, as described above, depending on the conditions under which the metal catalyst film is formed, if the energy beam irradiation is performed in an atmosphere containing a reducing gas, such as hydrogen gas and ammonia gas, an impurity that is trapped in the metal catalyst film and increases the resistance of the film, such as carbon and oxygen, may be advantageously prevented from being trapped in the film.

The area of the metal compound film that is not irradiated with the energy beam is washed off with a solvent, and then, a patterned metal catalyst film 114 is obtained (FIG. 1D). Using the metal catalyst film formed in this way as a seed, electroless plating or electroplating is performed to form a plating layer 115 composed of a wiring-forming metal (FIG. 1E). Here, the plating wiring-forming metal is deposited only in the metal catalyst precipitation area using the previously formed metal catalyst film as a seed, and the remaining area is not plated with the wiring-forming metal. Accordingly, the resulting plating pattern corresponds to the wiring pattern to be finally formed, and therefore, if spaces between the adjacent wires in the pattern are narrow, the wires can be prevented from being conductive, or an insulation failure can be prevented. Thus, a finer wiring pattern can be formed on the printed circuit board.

To stack another wiring pattern on the single-layered wiring pattern thus formed, a photosensitive resin or thermosetting pre-preg is applied and cured, thereby forming a first insulating layer 116, and then, a via hole 117 is formed at a desired area by laser irradiation or the like (FIG. 1F). As required, the surface is planarized with a polisher or the like.

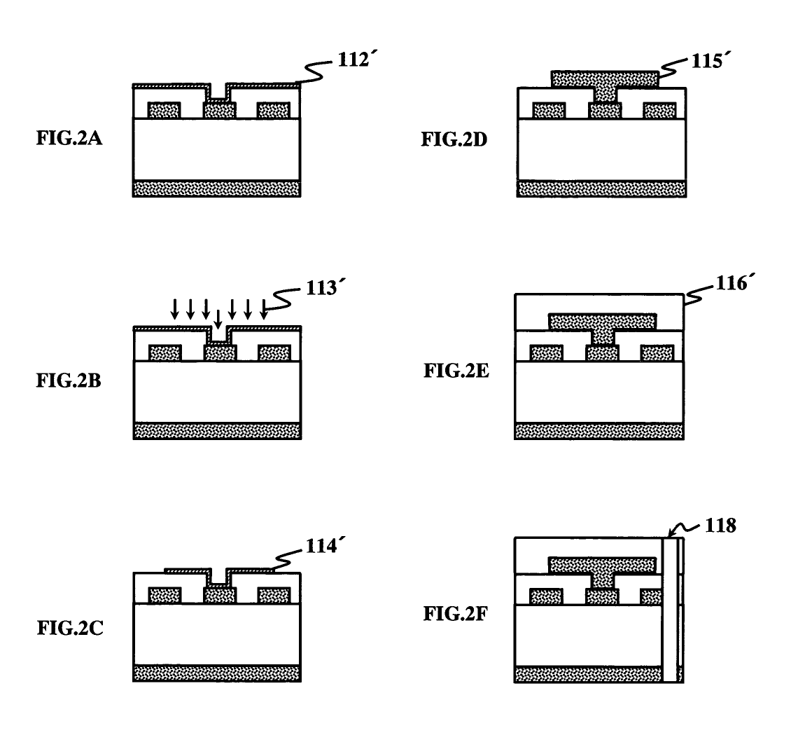

Then, as shown in FIGS. 2A to 2E, a metal compound film 112′ is formed, the metal compound film 112′ is irradiated with an energy beam 113′, a metal catalyst film 114′ is formed, and then, a plating layer 115′ to form a second layer of metal wiring and a second insulating layer 116′ are formed. The forming process thereof is substantially the same as the process shown in FIGS. 1B to 1F, and therefore, detailed description thereof will be omitted. FIG. 2F is a diagram for illustrating an optional step of forming a through hole 118. The through hole 118 can be formed with a drill or later processing apparatus, for example.

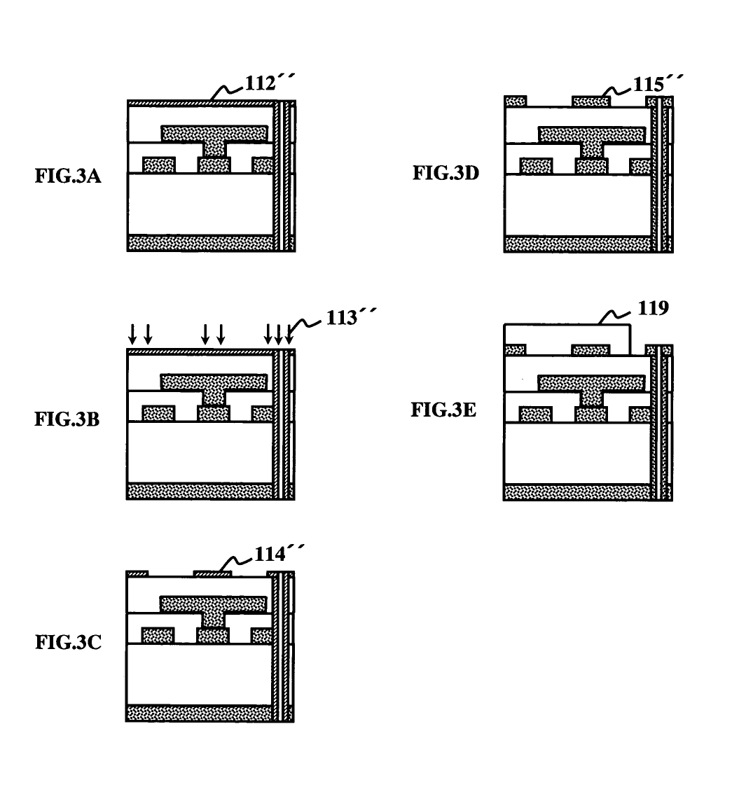

Then, as shown in FIGS. 3A to 3D, a metal compound film 112″ is formed, the metal compound film 112″ is irradiated with an energy beam 113″, a metal catalyst film 114″ is formed, and then, a plating layer 115″ to form a third layer of metal wiring is formed. The forming process thereof is substantially the same as the process shown in FIGS. 1B to 1E. Finally, a final coating 119, such as an insulating coating and a solder resist, is formed to complete the printed circuit board (FIG. 3E).

It will be apparent that four or more layers of wiring pattern can be formed by repeating the process described above a required number of times. Furthermore, while FIGS. 1A to 1F, FIGS. 2A to 2F and FIGS. 3A to 3E show an example in which the wiring patterns are formed only on one principal surface of the substrate 111, a required number of layers of wiring pattern can be formed on the other principal surface, of course. On the contrary, considering the distortion of the substrate caused by the patterned film formation, it is preferred that the layers of wiring pattern are formed on the both principal surfaces of the substrate.

### Embodiment 2

An Embodiment 2 relates to a second example of the method of fabricating a printed circuit board according to the first aspect of the present invention and will be described with reference to FIGS. 1A to 1F, FIGS. 2A to 2F and FIGS. 3A to 3E, as in the embodiment 1. As described above, the printed circuit board shown in these drawings for illustration has three layers of wiring pattern on one side, and FIGS. 1A to 1F, FIGS. 2A to 2F and FIGS. 3A to 3E correspond to procedures of forming a wiring pattern of a first layer, a wiring pattern of a second layer and a wiring pattern of a third layer, respectively.

First, a substrate 111, which is an insulating planar substrate, is prepared (FIG. 1A), and a solvent containing an organic or inorganic metal compound containing a metal catalyst serving as a seed for plating is applied to the both principal surfaces of the substrate 111 and dried to form a metal compound film 112 (FIG. 1B). The substrate 111 used herein is aplastic substrate, which is a material whose surface area can be locally molten, ablated or chemically modified by irradiation with an energy beam in the area corresponding to the irradiation, such as polyimide, epoxy, bismaleimide triazine, polyphenylene ether, polyacetal and phenol.

In addition, palladium acetate, which is an organic metal compound, is selected as the metal compound, and Pd therein is precipitated as the metal catalyst. An acetone solvent containing the metal compound is applied uniformly to the substrate 111 by coating so that the thickness of the metal compound film resulting from drying of the solvent is equal to or more than 0.1 μm and equal to or less than 0.5 μm, preferably equal to or more than 0.2 μm and equal to or less than 0.5 μm, and more preferably equal to or more than 0.3 μm and equal to or less than 0.5 μm.

Then, the area of the metal compound film 112 corresponding to a desired pattern is irradiated with an energy beam 113, such as an electron beam, to precipitate the metal catalyst in the irradiated area (FIG. 1C). Here, an electron beam is used as the energy beam. The diameter of the irradiating beam is reduced to the width of the desired wiring pattern, and the acceleration voltage thereof is determined within a range from 3 keV to 15 keV. As desired, a required number of irradiations can be performed.

The energy beam irradiation is performed by scanning the metal compound film with the energy beam in such a manner that the plating metal wiring on the metal catalyst film forms the wiring pattern on the printed circuit board, or using a patterning mask for allowing the energy beam to be incident only on the area corresponding to the wiring pattern to be formed. An energy beam irradiating apparatus used therefor will be described later.

In addition, as described above, depending on the conditions under which the metal catalyst film is formed, if the energy beam irradiation is performed in an atmosphere containing a reducing gas, such as hydrogen gas and ammonia gas, an impurity that is trapped in the metal catalyst film and increases the resistance of the film, such as carbon and oxygen, may be advantageously prevented from being trapped in the film.

The area of the metal compound film that is not irradiated with the energy beam is washed off with a solvent, and then, a patterned metal catalyst film 114 is obtained (FIG. 1D). Using the metal catalyst film formed in this way as a seed, electroless plating or electroplating is performed to form a plating layer 115 composed of a wiring-forming metal (FIG. 1E). Here, the plating wiring-forming metal is deposited only in the metal catalyst precipitation area using the previously formed metal catalyst film as a seed, and the remaining area is not plated with the wiring-forming metal. Accordingly, the resulting plating pattern corresponds to the wiring pattern to be finally formed, and therefore, if spaces between the adjacent wires in the pattern are narrow, the wires can be prevented from being conductive, or an insulation failure can be prevented. Thus, a finer wiring pattern can be formed on the printed circuit board.

To stack another wiring pattern on the single-layered wiring pattern thus formed, a photosensitive resin or thermosetting pre-preg is applied and cured, thereby forming a first insulating layer 116, and then, a via hole 117 is formed at a desired area by laser irradiation or the like (FIG. 1F). As required, the surface is planarized with a polisher or the like.

Then, as shown in FIGS. 2A to 2E, a metal compound film 112′ is formed, the metal compound film 112′ is irradiated with an energy beam 113′, a metal catalyst film 114′ is formed, and then, a plating layer 115′ to form a second layer of metal wiring and a second insulating layer 116′ are formed. The forming process thereof is substantially the same as the process shown in FIGS. 1B to 1F. FIG. 2F is a diagram for illustrating an optional step of forming a through hole 118. The through hole 118 can be formed with a drill or later processing apparatus, for example.

Then, as shown in FIGS. 3A to 3D, a metal compound film 112″ is formed, the metal compound film 112″ is irradiated with an energy beam 113″, a metal catalyst film 114″ is formed, and then, a plating layer 115″ to form a third layer of metal wiring is formed. The forming process thereof is substantially the same as the process shown in FIGS. 1B to 1E. Finally, a final coating 119, such as an insulating coating and a solder resist, is formed to complete the printed circuit board (FIG. 3E).

According to this embodiment, to enhance the adhesion of the metal catalyst film to the underlying substrate, the metal compound or granular metal serving as the plating catalyst for the metal wiring is dispersed in a liquid or granular binder that is the same material as or highly compatible with the substrate on which the metal catalyst film is formed, and the binder is applied to the substrate.

Specifically, if the substrate 111 is made of polyphenylene ether, polyphenylene ether is used also as the binder, and the granular binder is dissolved in toluene solution, which is a good solvent for polyphenylene ether, and an adequate amount of the toluene solution is added to the metal-compound-containing solvent to form a solution to be applied. As described above, the average diameter of the granular binder particles is determined within a range from 0.1 to 10 μm, considering the line width of the wiring obtained by plating and the precision of the finished surface.

An acetone solution of palladium acetate containing an adequate amount of a toluene solution in which a powder of a granular binder made of polyphenylene ether is dispersed was applied to the surface of the substrate made of polyphenylene ether, dried at the room temperature, and then irradiated with an electron beam. The energy of the electron beam was from 10 to 15 keV, the current value was 4.5 to 8 μA, and the irradiation duration was 30 minutes.

When the granular binder of polyphenylene ether is irradiated with the electron beam, melting, physical bonding or chemical reaction of the binder occurs, the binder and the substrate surface are firmly bonded to each other after the energy beam irradiation, and the adhesion of the metal catalyst film to the substrate is enhanced.

To confirm the enhancement of the adhesion of the metal catalyst film to the substrate, the metal catalyst film was washed with ethanol, electroless-plated with copper, and then electroplated with copper to a thickness of 15 μm to 17 μm, and then, a peeling test of the plating film was performed. Then, while the peel strength of the plating film formed by simply applying the acetone solution of palladium acetate was about 60 g/cm, the peel strength of the plating film according to this embodiment that was formed using the granular binder of polyphenylene ether was about 300 g/cm. Thus, it was confirmed that the peel strength was enhanced approximately fivefold.

It will be apparent that four or more layers of wiring pattern can be formed by repeating the process described above a required number of times. Furthermore, while FIGS. 1A to 1F, FIGS. 2A to 2F and FIGS. 3A to 3E show an example in which the wiring patterns are formed only on one principal surface of the substrate 111, a required number of layers of wiring pattern can be formed on the other principal surface, of course. On the contrary, considering the distortion of the substrate caused by the patterned film formation, it is preferred that the layers of wiring pattern are formed on the both principal surfaces of the substrate.

### Embodiment 3

Referring to an embodiment 3, there will be described a first configuration of a patterning apparatus (a substrate fabricating apparatus) for fabricating a printed circuit board according to the first aspect of the present invention.

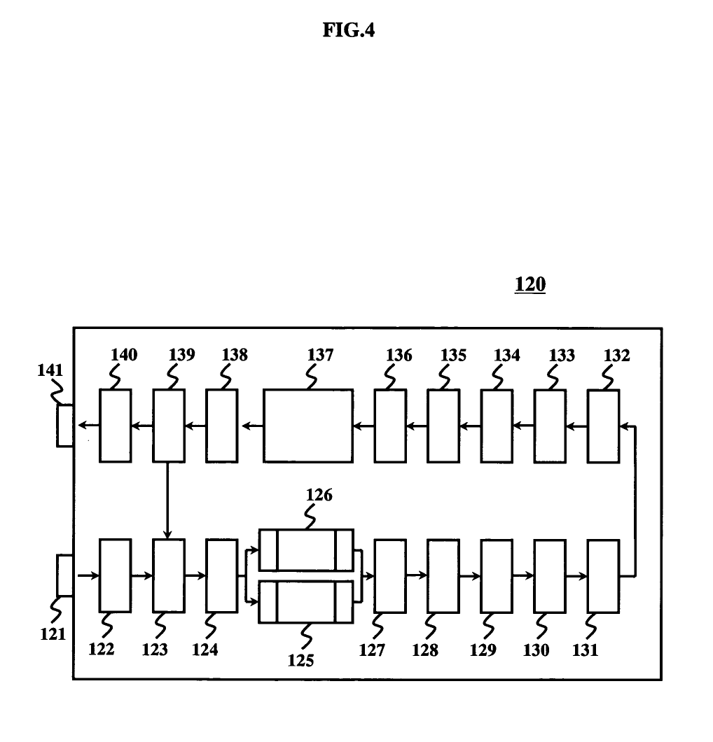

FIG. 4 is a conceptual diagram for illustrating the configuration of the patterning apparatus. A patterning apparatus 120 comprises at least a unit for forming a metal compound film, an energy beam irradiation unit, a washing unit for removing a metal compound film that has not been irradiated with the energy beam, a plating unit for plating a metal catalyst film formed by irradiation with the energy beam with a wiring-forming metal, a unit for applying an insulating film for surface protection and curing the insulating film, and a unit for forming a via hole or through hole.

The patterning apparatus 120 has a carrier unit for carrying a substrate (a printed circuit board, a silicon wafer or the like), which has a holding mechanism comprising a holding table for holding the substrate and a carriage arm for carrying the substrate. The patterning apparatus is controlled by a controller so as to carry the substrate held by the holding mechanism sequentially from the applying unit to the energy beam irradiation unit, from the energy beam irradiation unit to the washing unit, from the washing unit to the metal plating unit, from the metal plating unit to an insulating film applying unit, from the insulating film applying unit to an insulating film curing unit, and from the insulating film curing unit to the hole forming unit. Here, the carriage arm is to carry the substrate between the units described above. For example, a plurality of arms may be provided so that a different arm can be used for each unit, such as a vacuum unit, the metal plating unit and a polishing unit.

In the example shown in FIG. 4, the patterning apparatus 120 comprises a substrate inlet 121, a first washing tank 122, a solvent applying unit 123 for applying a solvent containing a metal compound, a first drying unit 124, an electron beam irradiation unit 125 of a scan-writing type having a load lock mechanism, an electron beam irradiation unit 126 of a mask type having a load lock mechanism, a second washing tank 127 for washing the substrate having been irradiated with the electron beam with a solvent, a second drying unit 128, a first pre-plating treatment unit 129 that performs a required treatment on the substrate surface before electrolessly plating a metal catalyst film with a wiring-forming metal, an electroless-plating unit 130, a third washing tank 131, a second pre-plating treatment unit 132 that performs a required treatment on the substrate surface before electroplating the metal catalyst film with a wiring-forming metal, an electroplating unit 133, a fourth washing tank 134, an insulating film applying unit 135 for applying an insulating film serving as a protective film, an insulating film curing unit 136 for curing the applied insulating film, a polisher 137 for planarizing the film formed on the substrate, a laser processing unit 138 for forming a via hole or through hole at a desired location in the substrate, a fifth washing tank 139, a testing unit 140 that determines whether the printed circuit board is good or defective, and a printed circuit board outlet 141.

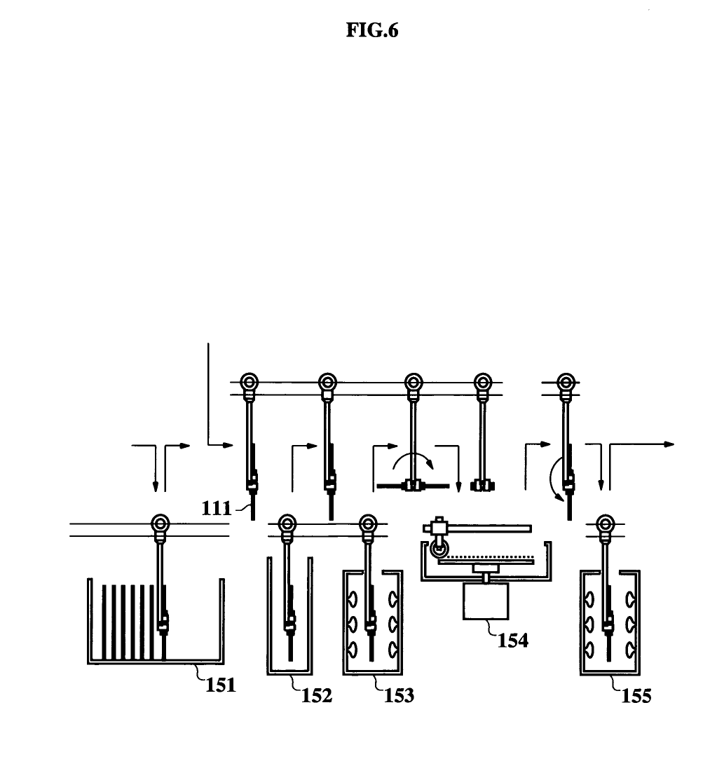

As described later with reference to FIG. 6, the substrate introduced into the patterning apparatus 120 through the substrate inlet 121 is carried through the apparatus by being handled with a hook or a robot hand. Once introduced into the patterning apparatus, the substrate is washed with a liquid that does not dissolve the substrate or clean air in the first washing tank 122 and then fed to the applying unit 123. In the solvent applying unit 123, a solvent containing a metal compound containing a metal catalyst is applied to the substrate by an appropriate technique, such as spin-coating, bar-coating, spray-coating, or dipping, and the substrate is dried in the first drying unit 124 to evaporate any excess solvent, thereby forming a metal compound film.

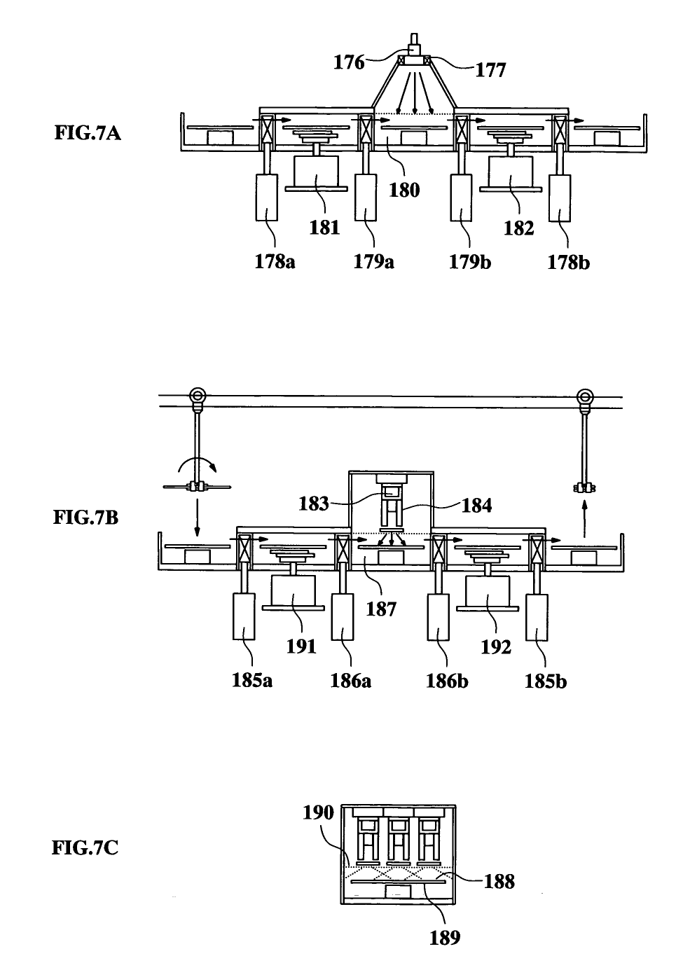

The metal compound film thus formed is irradiated with the electron beam. Here, as described later with reference to FIG. 7, depending on the purpose or conditions of the electron beam irradiation, one of the electron beam irradiation unit 125 of the scan-writing type and the electron beam irradiation unit 126 of the mask type is selected.

For example, in the case where the number of the printed circuit board to be produced is small, so that the cost of fabrication of the mask for electron beam irradiation is not reasonable, or where scanning the metal compound film on the substrate with the electron beam is enough, the electron beam irradiation unit 125 of the scan-writing type is used for irradiation.

On the other hand, in the case where the number of the printed circuit board to be produced is large, and the cost of fabrication of the mask for electron beam irradiation is reasonable, or where scanning the metal compound film on the substrate with the electron beam cannot provide an adequate throughput, the electron beam irradiation unit 126 of the mask type is used for irradiation. Such electron beam exposure will be described later in detail with reference to another embodiment.

After the electron beam irradiation is completed, the substrate is fed to the second washing tank 127, where the substrate is washed with an alcohol solvent or the solvent as that used for forming the metal compound film. Through this washing, the metal compound film in the area that has not been irradiated with the electron beam is removed, remaining the patterned metal catalyst film.

The substrate is fed to the second drying unit 128, where any excess solvent on the substrate is adequately evaporated. Then, the substrate is fed to the first pre-plating treatment unit 129, where a pre-treatment required before electroless plating of the metal catalyst film with the wiring-forming metal is performed. Specifically, an acid cleaning treatment and an accelerating treatment are performed as the pre-treatment.

Then, plating of the substrate is performed in the electroless-plating unit 130, and the substrate is treated in the third washing tank 131 and the second pre-plating treatment unit 132. Then, electroplating of the substrate is performed in the electroplating unit 133, and thus, the substrate is plated with an enough amount of metal to function as the wiring.

The substrate is washed in the fourth washing tank 134 to complete the procedure of forming the single layer of wiring pattern. Then, an insulating film is applied to the substrate in the insulating film applying unit 135, and the applied insulating film is cured in the insulating film curing unit 136. In addition, as required, the film is planarized with the polisher 137, and a via hole or through hole is formed at a desired location in the substrate with the laser processing unit 138. Then, after the substrate is washed in the fifth washing tank 139, the testing unit 140 determines whether the substrate is good or defective as a printed circuit board, and the substrate is carried out through the outlet 141. If multiple layers of wiring are required, the substrate is fed from the fifth washing tank 139 to the applying unit 123 before fed to the testing unit 140, and the series of steps are repeated a required number of times. Once the multiple layers of wiring are completed, an insulating film functioning as a protective film is applied to the substrate in the insulating film applying unit 135, and the applied insulating film is cured in the insulating film curing unit 136.

### Embodiment 4

Referring to an embodiment 4, there will be described a second configuration of the patterning apparatus (substrate fabricating apparatus) for fabricating a printed circuit board according to the first aspect of the present invention and a system in which the patterning apparatus is connected to a host computer via a network.

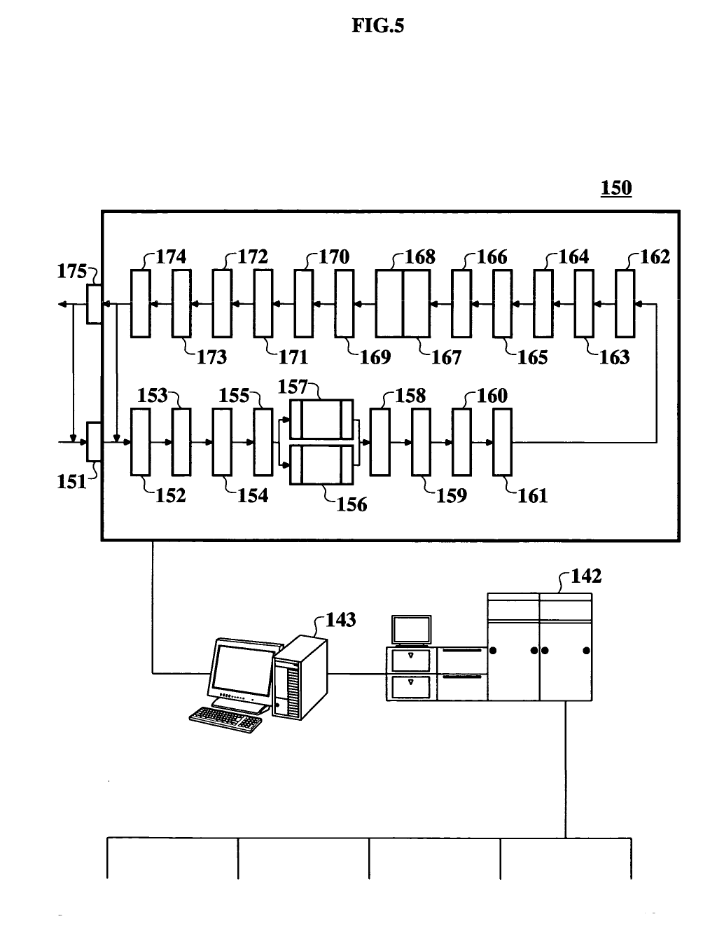

FIG. 5 is a conceptual diagram for illustrating the configuration of the patterning apparatus according to this embodiment. A patterning apparatus 150 comprises at least a unit for forming a metal compound film, an energy beam irradiation unit, a washing unit for removing a metal compound film that has not been irradiated with the energy beam, a plating unit for plating a metal catalyst film formed by irradiation with the energy beam with a wiring-forming metal, a unit for applying an insulating film for surface protection or an interlevel insulating layer required for multilayered wiring and curing the insulating film or layer, and a unit for forming a via hole or through hole. A control unit (PC) 143 of the patterning apparatus 150 is connected to a host computer 142 via a network. Therefore, the system in which the patterning apparatus 150 is connected to the host computer 142 via the network can be connected to an apparatus required for producing another product and manage or control the manufacturing process or the product quality control process in the entire factory collectively.

The patterning apparatus 150 has a carrier unit for carrying a substrate (a printed circuit board, a silicon wafer or the like), which has a holding mechanism comprising a holding table for holding the substrate and a carriage arm for carrying the substrate. The patterning apparatus is controlled by a controller so as to carry the substrate held by the holding mechanism sequentially from the applying unit to the energy beam irradiation unit, from the energy beam irradiation unit to the washing unit, from the washing unit to the metal plating unit, from the metal plating unit to an insulating film applying unit, from the insulating film applying unit to an insulating film curing unit, and from the insulating film curing unit to the hole forming unit. Here, the carriage arm is to carry the substrate between the units described above. For example, a plurality of arms may be provided so that a different arm can be used for each unit, such as a vacuum unit, the metal plating unit and a polishing unit.

In the configuration of the patterning apparatus shown in FIG. 5, the patterning apparatus 150 comprises a substrate inlet 151, a first washing tank 152, a first drying unit 153, a solvent applying unit 154 for applying a solvent containing a metal compound, a second drying unit 155, an electron beam irradiation unit 156 of a scan-writing type having a load lock mechanism, an electron beam irradiation unit 157 of a mask type having a load lock mechanism, a second washing tank 158 for washing the substrate having been irradiated with the electron beam with a solvent, a third drying unit 159, a first pre-plating treatment unit 160 that performs a required treatment on the substrate surface before electrolessly plating a metal catalyst film with a wiring-forming metal, an electroless-plating unit 161, a third washing tank 162, a second pre-plating treatment unit 163 that performs a required treatment on the substrate surface before electroplating the metal catalyst film with a wiring-forming metal, an electroplating unit 164, a fourth washing tank 165, a fourth drying unit 166, an insulating film applying unit 167 for applying an insulating film serving as a protective film, an insulating film curing unit 168 for curing the applied insulating film, a polisher 169 for planarizing the film formed on the substrate, a laser processing unit 170 for forming a via hole or through hole at a desired location in the substrate, a hole drilling unit 171, a fifth washing tank 172, a fifth drying unit 173, a testing unit 174 that determines whether the printed circuit board is good or defective, and a printed circuit board outlet 175.

As shown in FIG. 6, the substrate 111 introduced into the patterning apparatus 150 through the substrate inlet 151 is carried through the apparatus by being handled with a hook or a robot hand. Once introduced into the patterning apparatus, the substrate is washed with a liquid that does not dissolve the substrate or clean air in the first washing tank 152, dried in the first drying unit 153 and then fed to the solvent applying unit 154. In the solvent applying unit 154, a solvent containing a metal compound containing a metal catalyst is applied to the substrate by an appropriate technique, such as spin-coating, bar-coating, spray-coating, or dipping, and the substrate is dried in the second drying unit 155 to evaporate any excess solvent, thereby forming a metal compound film.

The metal compound film thus formed is irradiated with the electron beam. Here, as shown in FIGS. 7A and 7B, depending on the purpose or conditions of the electron beam irradiation, one of the electron beam irradiation unit 156 of the scan-writing type and the electron beam irradiation unit 157 of the mask type is selected.

For example, in the case where the number of the printed circuit board to be produced is small, so that the cost of fabrication of the mask for electron beam irradiation is not reasonable, or where scanning the metal compound film on the substrate with the electron beam is enough, the electron beam irradiation unit 156 of the scan-writing type is used for irradiation.

On the other hand, in the case where the number of the printed circuit board to be produced is large, and the cost of fabrication of the mask for electron beam irradiation is reasonable, or where scanning the metal compound film on the substrate with the electron beam cannot provide an adequate throughput, the electron beam irradiation unit 157 of the mask type is used for irradiation.

FIGS. 7A and 7B are schematic diagrams illustrating the configurations of the electron beam irradiation unit 156 of the scan-writing type and the electron beam irradiation unit 157 of the mask type, respectively. FIG. 7C is a side view of the electron beam irradiation unit 157 of the mask type shown in FIG. 7B for illustrating an electron beam irradiation system thereof.

In the electron beam irradiation unit of the scan-writing type shown in FIG. 7A, the electron beam is emitted from an electron gun 176 downward in the unit while being deflected by a scan coil assembly 177. Of course, the scan coil assembly 177 is composed of two sets of coils arranged along the X axis and Y axis. In the lower space of the unit, there is provided a sample chamber 180 that is separated from load lock chambers by gate valves 178a, 179a and gate valves 178b, 179b that are provided on the substrate inlet side and the substrate outlet side, respectively, and maintained under vacuum. The substrate having a metal compound film formed thereon is placed in the sample chamber 180 by a carrier robot.

Then, a desired area of the substrate surface is irradiated with the electron beam deflected by the scan coil assembly 177 to precipitate the metal catalyst from the metal compound film in the irradiated area, thereby forming a patterned metal catalyst film. Here, a thick part of the pattern may be formed with a thick electron beam, and a thin part of the pattern may be formed with a thin electron beam. In addition, depending on the line width, patterning may be conducted using one electron beam or using a required number of electron beams.

The electron beam irradiation may be conducted with the electron beam irradiation system and the sample chamber being provided in the same vacuum chamber, or may be conducted with the electron beam irradiation system and the sample chamber being provided in the separate vacuum chambers as shown in FIG. 7B. In the latter case, the electron beam irradiation system and the sample chamber are separated from each other by a partition. The partition that separates the electron beam irradiation system and the sample chamber from each other may be an electron beam transmissive film having a thickness equal to or less than 5 μm and equal to or more than 1 μm made of an aluminum alloy, a titanium alloy or SiO₂, for example. With such a configuration, the electron beam irradiation system can be prevented from being contaminated with a gas from the substrate or the like, and thus, the life of the filament (not shown) of the electron gun 176 can be extended.

In the electron beam irradiation unit of the mask type shown in FIG. 7B, the electron beam is emitted downward in the unit by an electron beam tube 184. In the lower space of the unit, there is provided a sample chamber 187 that is separated from load lock chambers by gate valves 185a, 186a and gate valves 185b, 186b that are provided on the substrate inlet side and the substrate outlet side, respectively, and has the inner pressure maintained. A substrate 189 having a metal compound film formed thereon is placed in the sample chamber 187, and a mask 188 having a desired pattern is disposed above the substrate 189.

The electron beam emitted from above the substrate 189 passes through only the openings in the mask 188 and reaches the surface of the substrate 189 to precipitate the metal catalyst from the metal compound film in the area irradiated with the electron beam, thereby forming a patterned metal catalyst film. In the configuration shown in FIG. 7B, in order that the vacuum chamber housing the electron beam tube 184 and the sample chamber 187 can have different degrees of vacuum, a window 190 for transmitting the electron beam is provided at a lower part of the upper vacuum chamber housing the electron beam tube 184. The substrate 189 is carried from the substrate inlet of the electron beam irradiation unit to a load lock chamber, and from the load lock chamber to the sample chamber 187 and placed in the sample chamber 187 by a carrier robot 191. Once the electron beam irradiation is completed, the substrate 189 is carried from the sample chamber 187 to a load lock chamber, and from the load lock chamber to the substrate outlet by a carrier robot 192.

If the electron beam irradiation can be conducted with the pressure in the sample chamber 187 being at the atmospheric pressure, there is an advantage that there is no need of taking the substrate in and out of the vacuum chamber, and thus, the throughput is improved. In a non-vacuum atmosphere, the electron beam has a larger diameter because the beam is dispersed by gas molecules. In the case where the line width of the pattern to be written is on the order of 30 μm, the electron beam irradiation can be accomplished adequately by adjusting the clearance between the window 190 for transmitting the electron beam and the substrate 189 to be irradiated with the electron beam to be equal to or less than 1 mm, preferably equal to or less than 0.5 mm. Furthermore, in a non-vacuum atmosphere, the electron beam ionizes gas molecules in the atmosphere, such as N₂ and Ar. However, the amount of the ionized gas molecules is quite small, and therefore, there arises no problem.

In the case where such a substrate is disposed out of the vacuum chamber, the electron beam irradiation can be conducted more effectively by filling the space in which the substrate and the window for transmitting the electron beam are disposed with an inert gas, such as helium and argon, or a gas that is less reactive with another material, such as nitrogen.

In addition, in the case where the substrate is disposed out of the vacuum chamber, the efficiency of precipitation of the metal catalyst by electron beam irradiation can be increased by filling the space in which the substrate is disposed with an active gas, such as oxygen, hydrogen and a halogen, that is effective for decomposition of an organic constituent. In this case, if there is a possibility of deterioration of the material of the window for transmitting the electron beam or deposition of a material on the window, in order to avoid such a phenomenon, there can be provided a mechanism that locally supplies an inert gas to produce an inert gas atmosphere around the window.

Here, both the electron beam irradiation units have respective predetermined degrees of vacuum required for electron beam irradiation. Preferably, the degree of vacuum of the electron beam irradiation unit 156 of the scan-writing type is 10⁻⁴ Pa or lower, and the degree of vacuum of the electron beam irradiation unit 157 of the mask type falls within a range from 10² Pa to the atmospheric pressure.

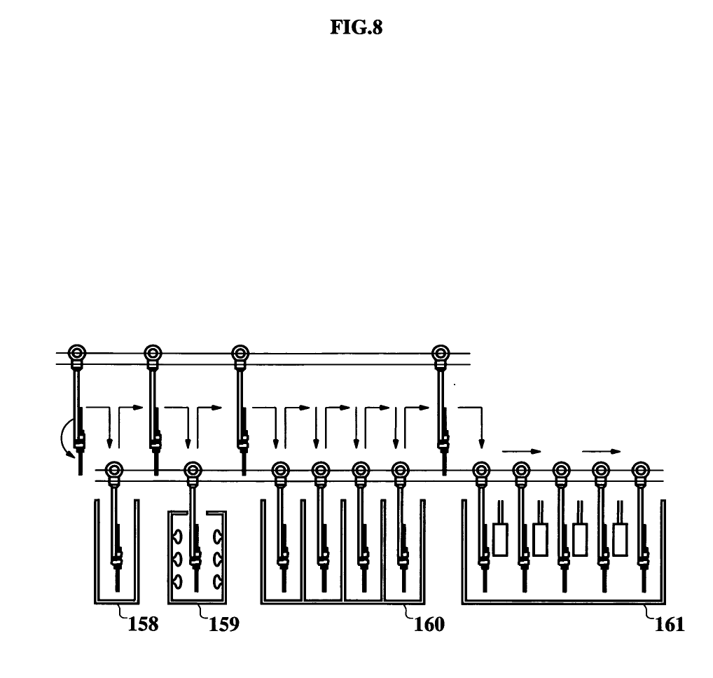

As shown in FIG. 8, after the electron beam irradiation is completed, the substrate is fed to the second washing tank 158, where the substrate is washed with an alcohol solvent or the solvent as that used for forming the metal compound film. Through this washing, the metal compound film in the area that has not been irradiated with the electron beam is removed, remaining the patterned metal catalyst film.

The substrate is fed to the third drying unit 159, where any excess solvent on the substrate is adequately evaporated. Then, the substrate is fed to the first pre-plating treatment unit 160, where a pre-treatment required before electroless plating of the metal catalyst film with the wiring-forming metal is performed. Specifically, an acid cleaning treatment and an accelerating treatment are performed as the pre-treatment.

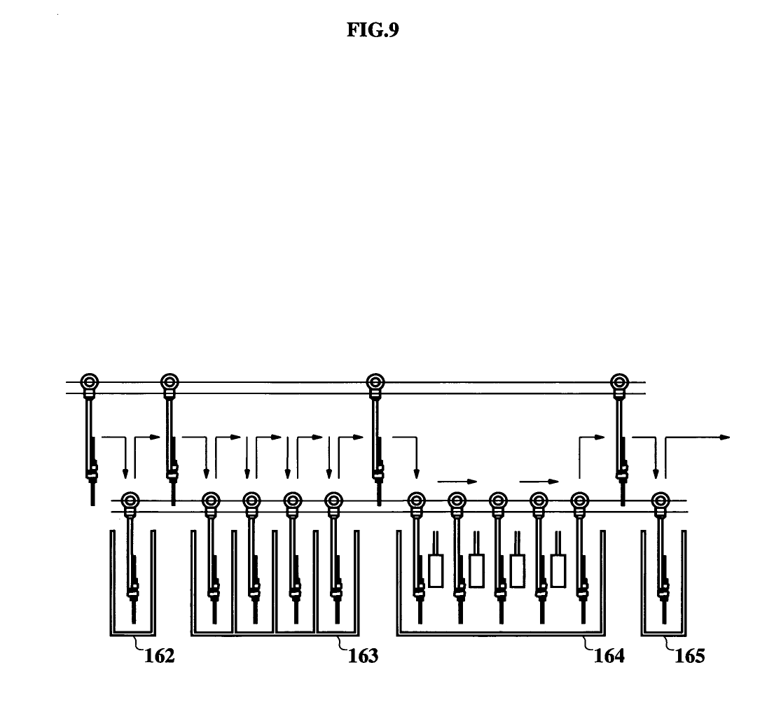

Then, plating of the substrate is performed in the electroless-plating unit 161, and as shown in FIG. 9, the substrate is treated in the third washing tank 162 and the second pre-plating treatment unit 163. Then, electroplating of the substrate is performed in the electroplating unit 164, and thus, the substrate is plated with an enough amount of metal to function as the wiring.

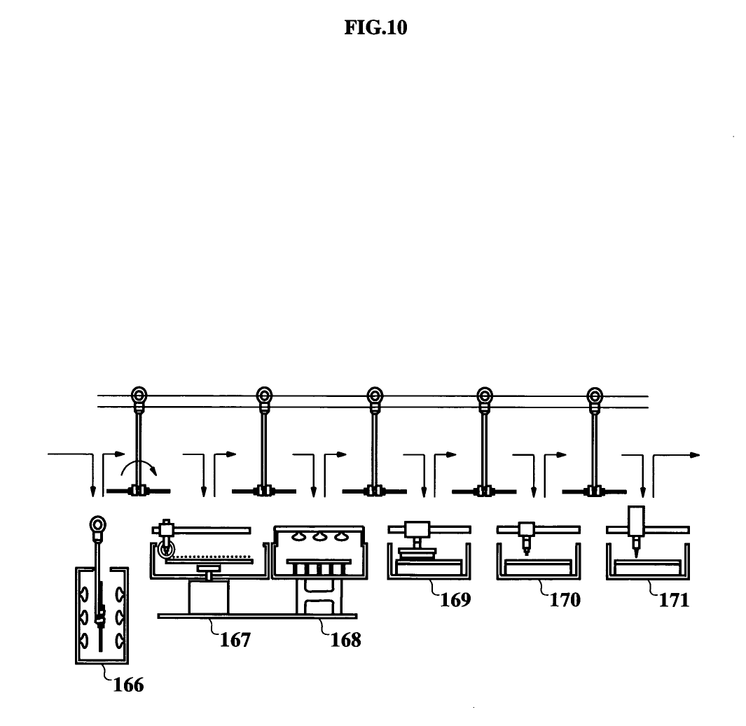

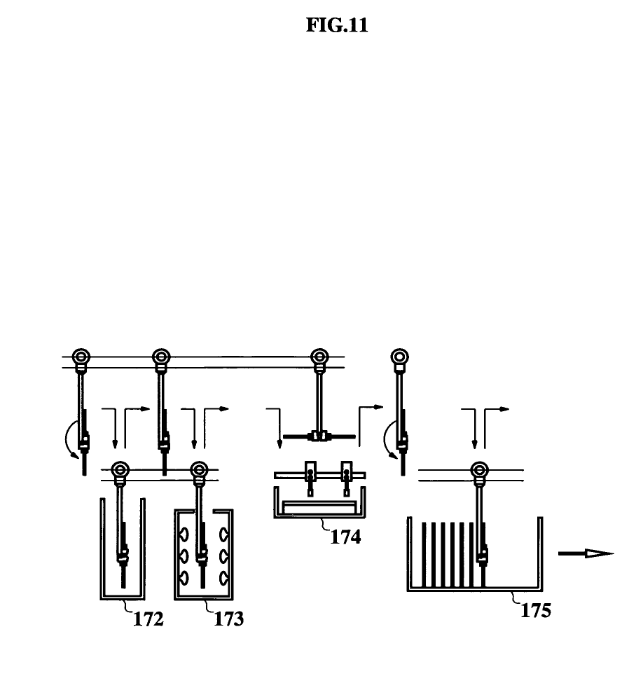

The substrate is washed in the fourth washing tank 165 to complete the procedure of forming the single layer of wiring pattern. Then, as shown in FIG. 10, the substrate is dried in the fourth drying unit 166, an insulating film is applied to the substrate in the insulating film applying unit 167, and the applied insulating film is cured in the insulating film curing unit 168. As required, the film is planarized with the polisher 169, and a via hole or through hole is formed at a desired location in the substrate with the laser processing unit 170. In addition, as required, a hole is formed in the substrate with the hole drilling unit 171. Then, as shown in FIG. 11, after the substrate is washed in the fifth washing tank 172, the substrate is dried in the fifth drying unit 173. Furthermore, the testing unit 174 determines whether the substrate is good or defective as a printed circuit board, and the substrate is carried out through the outlet 175. If multiple layers of wiring are required, the substrate is fed from the testing unit 174 to the first washing tank 152, and the series of steps are repeated a required number of times. In this case, since wiring patterns of the layers are different from each other, the control unit 143 controlling the patterning apparatus 150 provides information about the wiring pattern of each layer to the electron beam irradiation unit 156 of the scan-writing type or the electron beam irradiation unit 157 of the mask type. Once the multiple layers of wiring are completed, an insulating film functioning as a protective film is applied to the substrate in the insulating film applying unit 167, and the applied insulating film is cured in the insulating film curing unit 168.

### Embodiment 5

An embodiment 5 relates to an example in which patterns having line widths of 25 μm and 12 μm were formed by electroless plating and electron beam irradiation using a mask according to the patterning method according to the present invention described above.

The substrate used in this example was a substrate made of epoxy resin (FR-4) having an approximate size of 18 mm by 18 mm. One principal surface of the substrate was spin-coated with an acetone solution containing palladium acetate in a ratio of 1 to 30, and the substrate was dried at the room temperature for four hours or more.

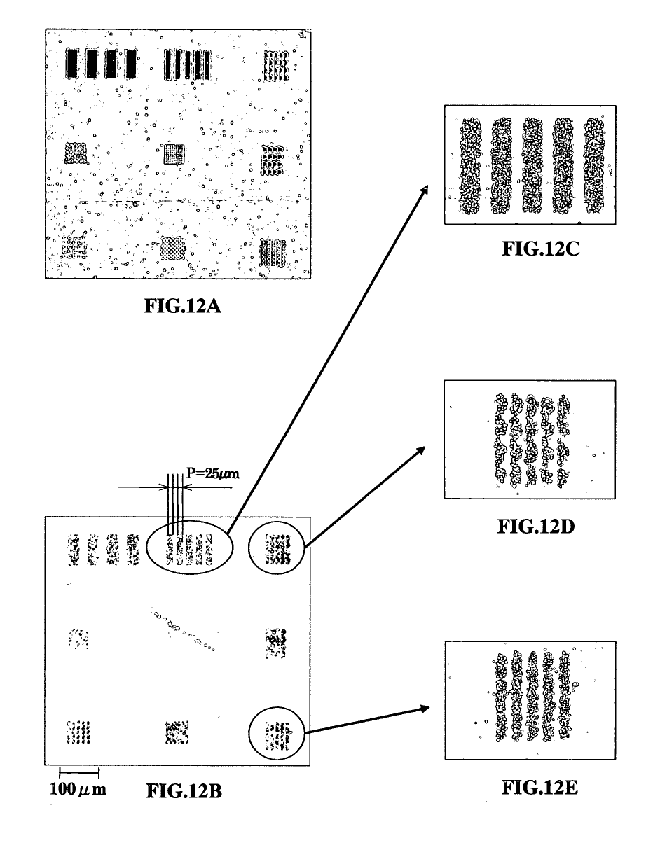

Following the drying of the substrate, a mask made of nickel (whose pattern is shown in FIG. 12A) was applied to the surface of the substrate that has been spin-coated with the solution, and the substrate with the mask was irradiated with an electron beam in a vacuum for 30 minutes, using a scan-type electron beam generator. The electron beam irradiation conditions were as follows: the applied voltage was 10 keV; the amount of the current of the electron beam was 4 μA; the beam diameter was 1.5 μm; and a square of a size of 10 mm by 10 mm was scanned in the same manner as the cathode ray tube of television.

Following the electron beam irradiation, the substrate surface was ultrasonic-cleaned in ethanol for 2 minutes, thereby washing off the palladium acetate in the area that has not been irradiated with the electron beam. Then, the substrate was acid-cleaned for 2 minutes using citric acid, and then was electroless-plated with copper to form a patterned copper wiring.

FIG. 12B shows an optical microscope photograph of a plating pattern formed in this way. As can be seen from the photographs shown in FIGS. 12D and 12E, a clear pattern of a line width of 12 μm as well as a pattern of a line width of 25 μm (FIG. 12C) are formed.

(Second Aspect: Patterning by Printing)

In the following, a printed circuit board and a method of fabricating the same according to a second aspect of the present invention will be described. It is noted that the present invention is not limited to the printed circuit board, but can be applied to any wiring on an insulating film (an insulating layer) formed on a semiconductor substrate, such as a silicon wafer, or any metal plating process for plating a planar or curved surface of a plastic material or a sheet of paper with a metal in an arbitrary pattern.

Again, unless otherwise specified, the term “substrate”, “base material” or the like used herein means not only a printed circuit board and a semiconductor substrate with an insulating film formed thereon, but also a common substrate or base material whose base on which a metal film is formed is an insulator. Furthermore, the “base material” includes the insulating film (insulating layer) on the substrate that serves as a base for patterning.

An example of a method of fabricating a substrate according to the present invention is a method of fabricating a printed circuit board. In this case, before electro-plating or electroless-plating the printed circuit board with a metal for forming wiring, a metal that functions as a “plating catalyst” for the wiring-forming metal is patterned by printing. Such patterning can be performed by ink jet printing using a solvent containing a desired metal as an ink material, micro-contact printing, or laser shot printing using a metal powder for direct printing. Then, using the metal catalyst film patterned on the printed circuit board as a seed for metal plating, a wiring pattern is formed so that only the metal catalyst film is plated with the wiring-forming metal. In other words, the plating metal is patterned because a second metal film of a plating metal, which is a second metal, is formed only on a previously pattern-printed film containing a catalyst metal, which is a first metal.

To precipitate the metal catalyst, a film of an organic metal compound or inorganic metal compound containing a metal serving as a plating catalyst is formed (printed) on a base material (printed circuit board), and the film is externally energized, such as irradiated with an energy beam, such as an electron beam, or externally heated or baked. Such external energization imparts energy required for precipitation only to the metal compound in the energized area. Thus, the chemical reaction of precipitation of the metal catalyst occurs only in the relevant area, and the metal catalyst can be precipitated in that area.

Again, unless otherwise specified, the term “metal compound” used in the following description means an organic metal compounds or inorganic metal compound. In addition, the term “metal compound” may also mean a metal complex. Furthermore, the term “printed circuit board” means not only a substrate with a metal wiring patterned thereon, but also a substrate that is yet to be mounted with a metal wiring (that is, a base material).

In order to precipitate a metal catalyst from an organic or inorganic metal compound containing a metal serving as a plating catalyst printed on a printed circuit board, the printed pattern may be irradiated with an energy beam, such as an electron beam, or the printed circuit board may be externally heated. When externally heating the printed circuit board, the printed circuit board may be treated in an oven whose temperature is controlled or may be baked on a plate of a metal or the like whose temperature is controlled (a hot plate, for example).

Following the irradiation with an energy beam, such as an electron beam, a post-film-formation heat treatment may be conducted to crystallize or sinter the metal catalyst film. The temperature of the heat treatment may be appropriately determined according to the object of the treatment, the kind of the metal catalyst or the base material being used. Such a post-film-formation heat treatment not only achieves crystallization or sintering of the metal catalyst film but also provides an advantage that the concentration of carbon or oxygen in the film, which is an impurity that is trapped in the film and increases the resistance of the film, is reduced. To reduce the amount of carbon or oxygen in the film, it is effective to heat-treat the film in an atmosphere of a reducing gas, such as hydrogen.

The precipitation of the metal catalyst from the metal compound in the area irradiated with an energy beam according to an example of the present invention is advantageous in that the series of steps of application, exposure and stripping of a photoresist, which are necessary in conventional patterning processes, can be omitted and that the temperature rise or heat diffusion to areas close to the irradiated area caused by the heat generated by the precipitation can be reduced significantly. To achieve this, the energy required to precipitate the metal catalyst can be imparted only to the metal compound film in the area to be patterned.

In general, in the case of precipitating a metal catalyst through thermal decomposition of a metal compound, the substrate has to be heated to a relatively high temperature in order to supply thermal energy enough to achieve precipitation. However, if the substrate is kept at such a high temperature, the metal catalyst precipitated on the substrate is crystallized rapidly, the crystal particles grow rapidly, and the precipitated metal particles become too large. Thus, it is difficult to enhance the linkage among metal particles to form a continuous film.

On the other hand, according to the energy beam irradiation method used in an example of the present invention, the energy required to precipitate the metal catalyst can be supplied locally with the substrate being kept at a low temperature. Thus, the metal catalyst can be precipitated on the substrate as amorphous fine particles of a uniform size uniformly distributed, and the metal catalyst film in which the crystal particles are firmly linked together can be formed. Of course, depending on the conditions, such as the area or thickness of the printed circuit board to be fabricated, the base material, or the line width of the pattern to be formed, the metal catalyst may be precipitated by externally heating the printed circuit board.

Here, the metal used as the plating catalyst is appropriately chosen according to the kind of the wiring-forming metal (copper (Cu), for example) and may be palladium (Pd), gold (Au), platinum (Pt), silver (Ag), indium (In), cobalt (Co) or tin (Sn), for example. In addition, the catalyst may be one of these metals or an alloy of two or more metals selected from among these metals.

The metal compound containing such a catalyst metal may be a metal carboxylate, a nitrate compound, a chloride, an iodine compound, a hydroxide, a fluorine compound, a sulfate compound, a sulfur compound or a compound of a chelate compound and an organic compound, or a metal compound composed of two or more of the above-described compounds. For example, the metal compound may be palladium acetate, tetraamine palladium acetate, indium acetate or indium 2-ethylhexanoate as an organic metal compound, or palladium chloride, palladium nitrate or indium chloride as an inorganic metal compound.

In the formation of a film of a metal compound containing a metal catalyst on a printed circuit board, it is important to form the film of a uniform thickness on the substrate. This is because, if the film thickness is not uniform, the density of the energy imparted by the energy beam varies with the place, and the extent of precipitation of the metal catalyst varies with the place, and because, if the film formation varies with the place on the substrate, a break or the like occurs in the final metal wiring pattern.

The solvent for the metal compound depends on the kind of the organic metal compound or inorganic metal compound used as the metal catalyst material and may be water, a hydrocarbon solvent, such as alcohol, ketone, acetone and toluene, or an acid solvent. The amount of the metal compound dissolved in the solvent is determined so that the thickness of the final metal compound film resulting from drying the solvent used for printing with a hot plate or the like is equal to or more than 0.1 μm and equal to or less than 0.5 μm, preferably so that the thickness is equal to or more than 0.2 μm and equal to or less than 0.5 μm, or more preferably so that the thickness is equal to or more than 0.3 μm and equal to or less than 0.5 Such determination of the film thickness is intended to assure the continuity of the metal catalyst film in the irradiated area even if the irradiating energy beam induces a chemical reaction of the organic metal compound or inorganic metal compound, and the volume thereof shrinks when the metal catalyst is precipitated. Specifically, if the metal compound film after the solvent is dried is too thin, the metal catalyst may be nonuniformly precipitated. If such nonuniform precipitation occurs, a defect, such as a pin hole, may occur in the metal catalyst film serving as a plating seed and inhibit uniform plating of the predetermined area to be patterned with the metal wiring. To surely avoid such a problem, the thickness of the printed metal compound film is preferably equal to or more than 0.3 μm.

The base material of the printed circuit board is an insulating material. In the case where energy beam irradiation is conducted for externally imparting energy to the substrate, materials whose surface can be chemically modified, molten or ablated locally in the irradiated area are preferably used. This is intended to make the metal catalyst precipitated by irradiation with the energy beam adhere to the substrate with reliability.

Specifically, the substrate surface may be molten to trap the metal catalyst in the substrate to an extremely shallow depth, or the substrate surface may be ablated to effectively increase the contact area between the metal catalyst and the substrate surface, or alternatively, the substrate surface may be chemically modified to enhance the bonding between the substrate and the metal catalyst, thereby raising the degree of adhesion therebetween. By choosing the substrate in this way, the metal catalyst film becomes hard to peel from the substrate during the subsequent plating step for forming the metal wiring.

As the material for the substrate, a plastic resin is preferably used. In the case where the base material is a plastic resin, the plastic resin may be one selected from a group consisting of polyimide, epoxy, bismaleimide triazine, polyphenylene ether, polyacetal and phenol, or may be a fiber-reinforced plastic resin based on a resin selected from the group described above.

For enhancing the adhesion of the metal catalyst film to the substrate, the metal compound or metal particles serving as the plating catalyst for the metal wiring may be effectively dispersed in a liquid binder and/or a granular binder that is the same as (or highly compatible with) the material of the substrate on which the metal catalyst film is to be formed. For example, a granular binder that is the same kind as and the same quality as the base material is dispersed or dissolved in the solvent for dissolving the metal compound serving as the plating catalyst for the metal wiring, and the solvent is applied onto the substrate. In the case where such a binder is used, the metal compound film resulting from drying the solvent contains the binder that is the same kind as and the same quality as the substrate material. However, irradiating the film with an energy beam can cause not only melting, physical bonding or chemical reaction in the irradiated area of the substrate surface but also melting, physical bonding or chemical reaction of the binder in the film, thereby firmly bonding the binder and the substrate surface to each other. Consequently, the adhesion of the metal catalyst film to the substrate can be enhanced.

For example, if polyphenylene ether is used as a binder, a granular binder is dissolved in toluene solution, which is a good solvent for polyphenylene ether, and an adequate amount of the toluene solution is added to the metal-compound-containing solvent to form a solvent for the printing ink.

Here, in the case where a granular binder is dispersed in the solvent, the diameter of the particles is preferably equal to or less than 10 μm and equal to or more than 0.1 μm, more preferably equal to or less than 5 μm and equal to or more than 0.1 μm, and further preferably equal to or less than 1 μm and equal to or more than 0.1 μm, considering the line width of the wiring obtained by plating and enhancement of the precision of the finished surface. The material of the binder may not be the same as the base material but can be selected from among those that are highly compatible with the base material. Here, the term “compatible” means that a material is in a state where it can easily be mixed with or chemically react with another material or a state where it can easily adhere to another material due to a significant intermolecular force.

Of course, the technique of using a binder can be used together with the technique of melting the base material surface to make the base material trap the metal catalyst to an extremely shallow depth, or the technique of ablating the base material surface to effectively increase the contact area between the metal catalyst and the base material surface, or the technique of chemically modifying the base material surface to enhance the bonding between the base material and the metal catalyst, thereby raising the degree of adhesion therebetween described above.

As for the energy beam used for precipitating the metal serving as the plating catalyst on the printed circuit board, an energy beam suitable for precipitating the metal in the metal compound selected as the metal catalyst material and patterning the precipitated metal into a desired shape is selected. For example, the energy beam may be an electron beam, a microwave, an ion beam, infrared rays, ultraviolet rays, vacuum ultraviolet rays, atomic beam, X-rays, γ-rays, visible light, or a laser beam. Furthermore, of course, the energy of the energy beam can be determined to fall within an appropriate range depending on the metal catalyst to be precipitated.

In the case where the electron beam is used as the energy beam, the applied voltage is appropriately determined considering the intended beam diameter on the irradiation area. Typically, it is determined to fall within a range from 3 keV to 300 keV. Here, if the applied voltage is too high, the energy density per unit area of the irradiation area is also too high, which may cause excessive melting of the base material surface, sublimation of the metal compound rather than precipitation of the metal catalyst, attacking of the electron beam only on the base material through the film on the surface thereof, or other disadvantageous effects. Thus, the energy value of the energy beam is preferably determined to fall within a range from 3 keV to 30 keV, and more preferably to fall within a range from 3 keV to 15 keV.

In the case where a microwave is used as the energy beam, depending on the size of the printed circuit board to be fabricated, a microwave oven for household use can be experimentally used to easily irradiate the printed circuit board with the energy beam, for example. The presence of water molecules is advantageous for heating by the microwave. In this case, it is convenient for precipitation of the catalyst metal that the printed circuit board is heated with the microwave oven before the applied printing ink containing the metal catalyst dries. Furthermore, to prevent the printing ink dry fast, it is advantageous to add a humectant, such as ethylene glycol, to the printing ink.

Then, using the patterned metal catalyst film on the substrate as a seed, only the seed is plated with a wiring-forming metal to form a wiring pattern. Of course, not only such a single-layered wiring pattern but also multi-layered wiring patterns can be formed.

According to the present invention, using a plastic film or sheet having a thickness equal to or less than 0.5 mm and equal to or more than 10 μm, preferably equal to or less than 0.3 mm and equal to or more than 20 μm, or more preferably equal to or less than 0.3 mm and equal to or more than 50 μm, as a base material, a flexible printed circuit board can be fabricated by forming a wiring pattern on the base material. In addition, a plurality of such flexible printed circuit boards are stacked to form a multilayer wiring.

In addition, according to the present invention, in the case where a plastic film or sheet is used as a base material to form a wiring pattern, a flexible printed circuit board can be fabricated by printing a pattern on the surface of the plastic film or sheet by an appropriate printing technique such as laser shot printing using a powder containing a single first metal or at least two kinds of first metals, baking the pattern to make it adhere to the surface of the plastic film or sheet, and then plating the pattern with a second metal contained in a plating solution using the first metal as a plating catalyst layer.

Here, in the case where a pattern is printed using a powder containing a metal catalyst by an appropriate technique, such as laser shot printing, if a granular binder that is the same as or highly compatible with the insulating base material is contained or mixed in the powder containing the metal catalyst, the binder and the base material surface are firmly bonded to each other after baking, and consequently, the adhesion of the metal catalyst film to the base material is enhanced.

The plating metal film on the plastic film or sheet is not exclusively applied to the flexible printed circuit board but can be applied to other uses. In applications other than the printed circuit board, the thickness of the film or sheet is not limited to fall within the range between 10 μm to 0.5 mm inclusive and can be determined so as to be suitable for the relevant application.

In the following, a method of patterning a metal film and a method of fabricating a printed circuit board according to the second aspect of the present invention will be described for illustration with reference to embodiments thereof.

### Embodiment 6

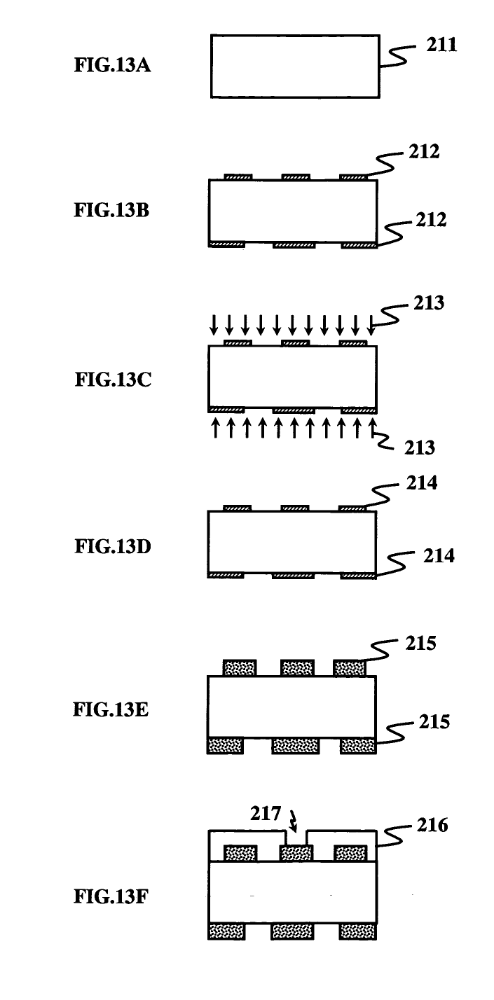

FIGS. 13A to 13F, FIGS. 14A to 14F, and FIGS. 15A to 15E are diagrams for illustrating a first example of a method of fabricating a printed circuit board according to the second aspect of the present invention, and the printed circuit board shown in these drawings for illustration has three layers of wiring pattern on one side. Here, FIGS. 13A to 13F, FIGS. 14A to 14F, and FIGS. 15A to 15E correspond to procedures of forming a wiring pattern of a first layer, a wiring pattern of a second layer and a wiring pattern of a third layer, respectively.

First, a base material 211, which is an insulating base material, is prepared (FIG. 13A). A desired pattern is printed on the both principal surfaces of the base material 211 using a solvent containing an organic or inorganic metal compound containing a metal catalyst serving as a seed for plating (or a solvent containing an organic or inorganic metal compound containing a metal catalyst serving as a seed for plating is applied to the both principal surfaces of the base material 211), and the base material 211 is dried to form a metal compound film 212 (FIG. 13B). The base material 211 used herein is a plastic substrate, which is a material whose surface area can be locally molten, ablated or chemically modified by irradiation with an energy beam in the area corresponding to the irradiation, such as polyimide, epoxy, bismaleimide triazine, polyphenylene ether, polyacetal and phenol.

In addition, palladium acetate, which is an organic metal compound, is selected as the metal compound, for example, and Pd therein is precipitated as the metal catalyst. Using an acetone solvent containing the metal compound, a wiring pattern is printed on the base material 211 so that the thickness of the metal compound film resulting from drying of the solvent is equal to or more than 0.1 μm and equal to or less than 0.5 μm, preferably equal to or more than 0.2 μm and equal to or less than 0.5 μm, and more preferably equal to or more than 0.3 μm and equal to or less than 0.5 μm.

Then, the area of the metal compound film 212 corresponding to the pattern is irradiated with an energy beam 213, such as an electron beam, to precipitate the metal catalyst in the printed pattern area (FIG. 13C). Here, an electron beam is used as the energy beam, and the acceleration voltage thereof is determined within a range from 3 keV to 15 keV. As desired, a required number of irradiations can be performed.

The energy beam irradiation may be performed by scanning the area of the printed desired pattern with the energy beam or by showering the energy beam on the whole area of the printed desired pattern. An energy beam irradiating apparatus used therefor will be described later.

In addition, as described above, depending on the conditions under which the metal catalyst film is formed, if the energy beam irradiation is performed in an atmosphere containing a reducing gas, such as hydrogen gas and ammonia gas, an impurity that is trapped in the metal catalyst film and increases the resistance of the film, such as carbon and oxygen, may be advantageously prevented from being trapped in the film.

Once the energy beam irradiation is completed, a patterned metal catalyst film 214 is obtained (FIG. 13D). Using the metal catalyst film formed in this way as a seed, electroless plating or electroplating is performed to form a plating layer 215 composed of a wiring-forming metal (FIG. 13E). Here, the plating wiring-forming metal is deposited only in the metal catalyst precipitation area using the previously formed metal catalyst film as a seed, and the remaining area is not plated with the wiring-forming metal. Accordingly, the resulting plating pattern corresponds to the wiring pattern to be finally formed, and therefore, if spaces between the neighboring wires in the pattern are narrow, the wires can be prevented from being conductive, or an insulation failure can be prevented. Thus, a finer wiring pattern can be formed on the printed circuit board.

To stack another wiring pattern on the single-layered wiring pattern thus formed, a photosensitive resin or thermosetting pre-preg is applied and cured, thereby forming a first insulating layer 216, and then, a via hole 217 is formed at a desired area by laser irradiation or the like (FIG. 13F). As required, the surface is planarized with a polisher or the like.

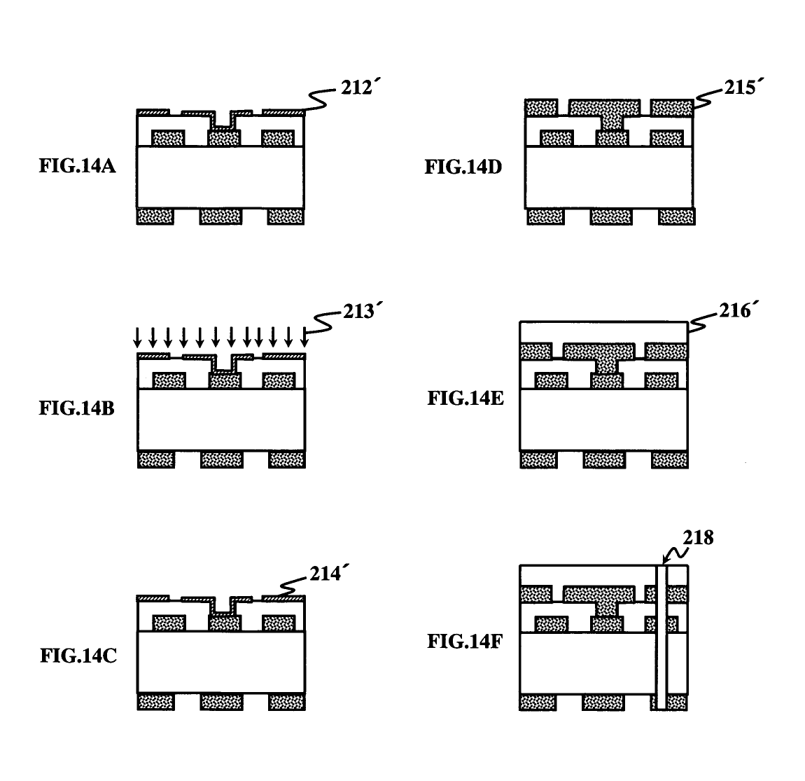

Then, as shown in FIGS. 14A to 14E, a metal compound film 212′ is formed, the metal compound film 212′ is irradiated with an energy beam 213′, a metal catalyst film 214′ is formed, and then, a plating layer 215′ to form a second layer of metal wiring and a second insulating layer 216′ are formed. The forming process thereof is substantially the same as the process shown in FIGS. 13B to 13F, and therefore, detailed description thereof will be omitted. FIG. 14F is a diagram for illustrating an optional step of forming a through hole 218. The through hole 218 can be formed with a drill or later processing apparatus, for example.

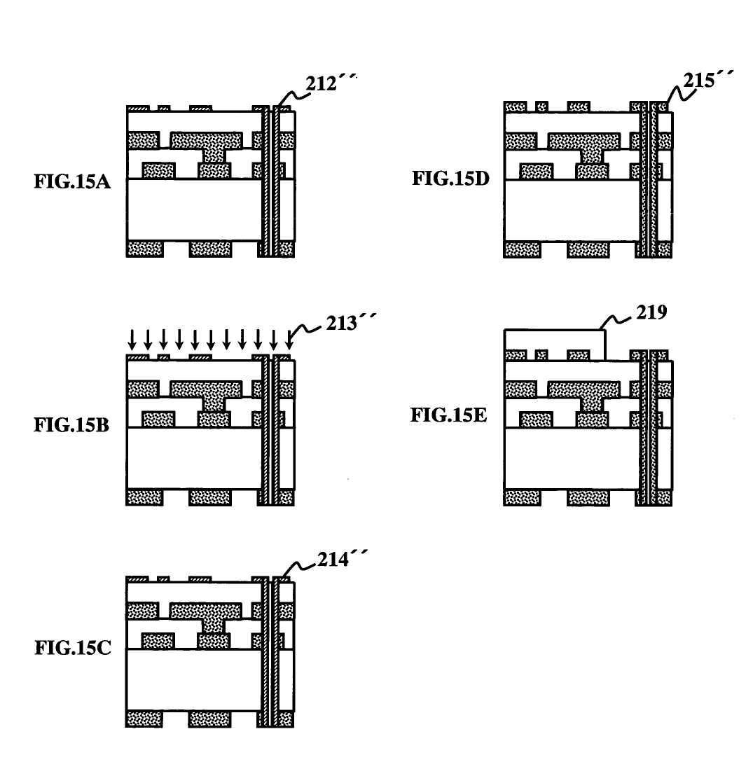

Then, as shown in FIGS. 15A to 15D, a metal compound film 212″ is formed, the metal compound film 212″ is irradiated with an energy beam 213″, a metal catalyst film 214″ is formed, and then, a plating layer 215″ to form a third layer of metal wiring is formed. The forming process thereof is substantially the same as the process shown in FIGS. 13B to 13F. Finally, a final coating 219, such as an insulating coating and a solder resist, is formed to complete the printed circuit board (FIG. 15E).

According to this embodiment, to enhance the adhesion of the metal catalyst film to the underlying substrate, the metal compound or granular metal serving as the plating catalyst for the metal wiring is dispersed in a liquid binder and/or a granular binder that is the same material as or highly compatible with the base material on which the metal catalyst film is printed.

It will be apparent that four or more layers of wiring pattern can be formed by repeating the process described above a required number of times. Furthermore, as for the second and third layers of wiring pattern, while FIGS. 14A to 14F and FIGS. 15A to 15E show an example in which the wiring patterns are formed only on one principal surface of the substrate 211, a required number of layers of wiring pattern can be formed on the other principal surface, of course. On the contrary, considering the distortion of the substrate caused by the patterned film formation, it is preferred that the layers of wiring pattern are formed on the both principal surfaces of the substrate.

### Embodiment 7

Referring to an embodiment 7, there will be described a configuration of a patterning apparatus (substrate fabricating apparatus) for fabricating a printed circuit board according to the second aspect of the present invention and a system in which the patterning apparatus is connected to a host computer via a network.

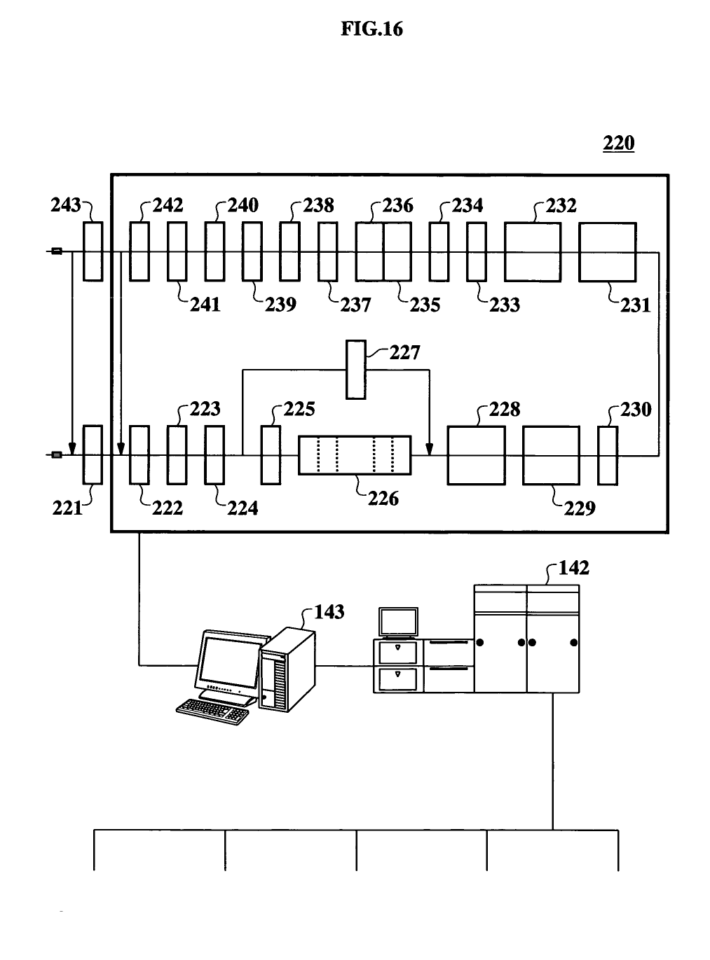

FIG. 16 is a conceptual diagram for illustrating the configuration of the patterning apparatus according to this embodiment. A patterning apparatus 220 comprises at least a unit for printing a metal compound film, an energy beam irradiation unit, a plating unit for plating a metal catalyst film formed by irradiation with the energy beam with a wiring-forming metal, a unit for applying an insulating film for surface protection or an interlevel insulating layer required for multilayered wiring and curing the insulating film or layer, and a unit for forming a via hole or through hole. A control unit (PC) 143 of the patterning apparatus 220 is connected to a host computer 142 via a network. Therefore, the system in which the patterning apparatus 220 is connected to the host computer 142 via the network can be connected to an apparatus required for producing another product and manage or control the manufacturing process or the product quality control process in the entire factory collectively.

The patterning apparatus 220 has a carrier unit for carrying a base material (a printed circuit board, a silicon wafer or the like), which has a holding mechanism comprising a holding table for holding the base material and a carriage arm for carrying the base material. The patterning apparatus is controlled by a controller so as to carry the base material held by the holding mechanism sequentially from the printing unit to the energy beam irradiation unit, from the energy beam irradiation unit to the metal plating unit, from the metal plating unit to an insulating film applying unit, from the insulating film applying unit to an insulating film curing unit, and from the insulating film curing unit to the hole forming unit. Here, the carriage arm is to carry the substrate between the units described above. For example, a plurality of arms may be provided so that a different arm can be used for each unit, such as a vacuum unit, the metal plating unit and a polishing unit.

In the configuration shown in FIG. 16, the patterning apparatus 220 comprises a base material inlet 221, a first washing tank 222, a first drying unit 223, a printing unit 224 that uses a solvent containing a metal compound, a second drying unit 225, an electron beam irradiation unit 226 having a load lock mechanism, a heating unit 227 that heats the solvent containing the metal compound used for printing, a first pre-plating treatment unit 228 that performs a required treatment on the substrate surface before electrolessly plating a metal catalyst film with a wiring-forming metal, an electroless-plating unit 229, a second washing tank 230, a second pre-plating treatment unit 231 that performs a required treatment on the substrate surface before electroplating the metal catalyst film with a wiring-forming metal, an electroplating unit 232, a third washing tank 233, a third drying unit 234, an insulating film applying unit 235 for applying an insulating film serving as a protective film or an interlevel insulating layer required for multilayered wiring, an insulating film curing unit 236 for curing the applied insulating film, a polisher 237 for planarizing the film formed on the substrate, a laser processing unit 238 for forming a via hole or through hole at a desired location in the substrate, a hole drilling unit 239, a fourth washing tank 240, a fourth drying unit 241, a testing unit 242 that determines whether the printed circuit board is good or defective, and a printed circuit board outlet 243.

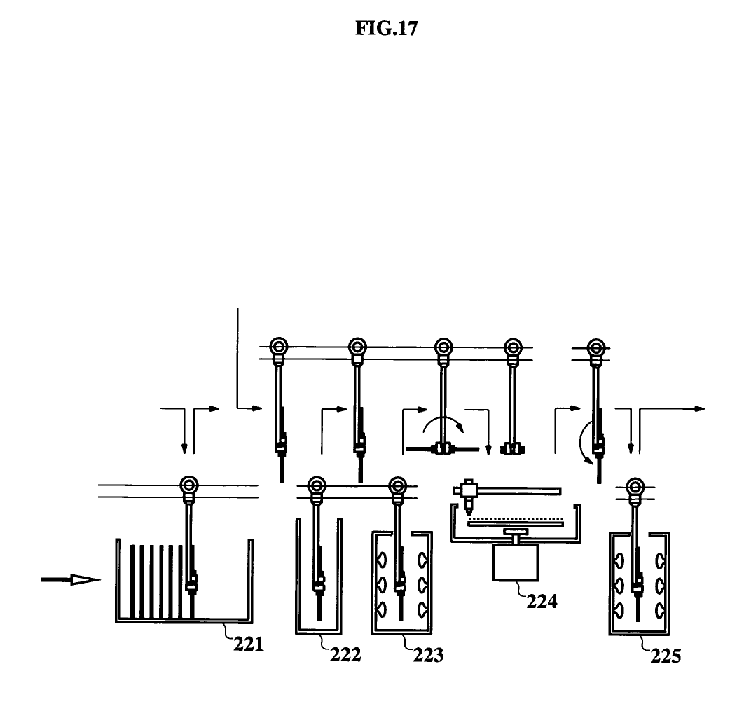

As shown in FIG. 17, the base material introduced into the patterning apparatus through the substrate inlet 221 is carried through the apparatus by being handled with a hook or a robot hand. Once introduced into the patterning apparatus, the base material is washed with a liquid that does not dissolve the base material or clean air in the first washing tank 222, dried in the first drying unit 233 and then fed to the printing unit 224. In the printing unit 224, a pattern is printed on the base material by an appropriate technique, such as ink jet printing, using a solvent containing a metal compound containing a metal catalyst.

Then, the base material is dried in the second drying unit 225 to evaporate any excess solvent, thereby forming a metal compound film. The metal compound film thus formed is irradiated with an electron beam in the electron beam irradiation unit 226 to precipitate the metal catalyst in the printed pattern.

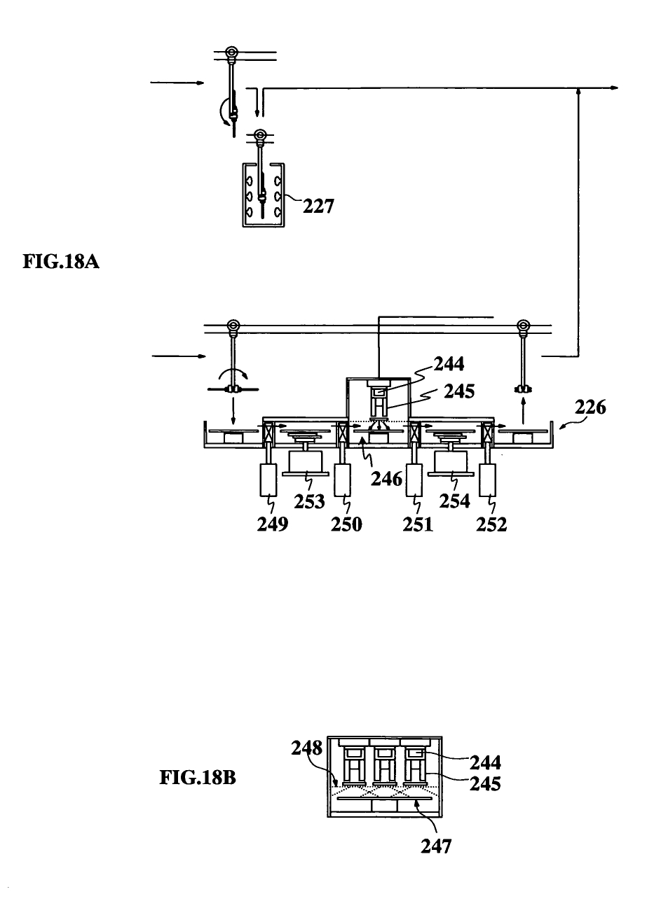

FIG. 18A is a diagram illustrating the base material being treated in the electron beam irradiation unit 226 and the heating unit 227. FIG. 18B is a side view of the electron beam irradiation unit 226 shown in FIG. 18A for illustrating an electron beam irradiation system thereof.

In the electron beam irradiation unit 226, electrons emitted from an electron gun 244 is accelerated in an electron beam tube 245 and then emitted from the electron beam tube 245, and the electron beam is radiated downward. In the lower space of the unit, there is provided a sample chamber 246 that is separated from load lock chambers by gate valves 249, 250 and gate valves 251, 252 provided on the substrate inlet side and the substrate outlet side, respectively, and has the inner pressure maintained. A base material 247 having a metal compound film printed thereon is placed in the sample chamber 246. The base material 247 is carried from the substrate inlet of the electron beam irradiation unit 226 to a load lock chamber, and from the load lock chamber to the sample chamber 246 and placed in the sample chamber 246 by a carrier robot 253.

The electron beam emitted from above the base material 247 passes downward through a window 248 for transmitting the electron beam and is incident on the surface of the base material 247, thereby precipitating a metal catalyst film from the metal compound film printed in the area irradiated with the electron beam. The base material 247 irradiated with the electron beam is carried from the sample chamber 246 to a load lock chamber, and from the load lock chamber to the substrate outlet of the electron beam irradiation unit 226 by a carrier robot 254.

The electron beam irradiation may be conducted with the electron beam irradiation system and the sample chamber being provided in the same vacuum chamber, or may be conducted with the electron beam irradiation system and the sample chamber being provided in the separate vacuum chambers as shown in FIG. 18A. In the latter case, the electron beam irradiation system and the sample chamber are separated from each other by a partition. The partition that separates the electron beam irradiation system and the sample chamber from each other may be an electron beam transmissive film having a thickness equal to or less than 5 μm and equal to or more than 1 μm made of an aluminum alloy, a titanium alloy or SiO₂, for example. With such a configuration, the electron beam irradiation system can be prevented from being contaminated with a gas evaporated from the substrate or the like, and thus, the life of the filament (not shown) of the electron gun 244 can be extended.

In order that the vacuum chamber housing the electron beam tube 245 and the sample chamber 246 can have different degrees of vacuum, the electron beam irradiation unit configured as shown in FIG. 18A has the window 248 for transmitting the electron beam that serves as a partition between the upper vacuum chamber housing the electron beam tube 245 and the sample chamber 246, as shown in FIG. 18B.

If the electron beam irradiation can be conducted with the pressure in the sample chamber 246 being at the atmospheric pressure, there is an advantage that there is no need of taking the substrate in and out of the vacuum chamber, and thus, the throughput is improved. In that case, the electron beam irradiation can be conducted with the pressure in the load lock chamber on the side of the inlet, the sample chamber 246 and the load lock chamber on the side of the outlet of the electron beam irradiation unit being kept at the atmospheric pressure. Alternatively, the electron beam irradiation can be conducted with the pressure in the sample chamber 246 being reduced to a pressure ranging from 10² Pa to the atmospheric pressure. Although the upper vacuum chamber housing the electron beam tube 245 is required to have a degree of vacuum of 10⁻⁵ Pa to b 10⁻⁴ Pa, evacuation of the sample chamber 246 to about 10² Pa can be accomplished in a shorter time than evacuation to about 10⁻⁴ Pa to 10⁻⁵ Pa, and thus, the throughput is improved.

In a non-vacuum atmosphere, the electron beam has a larger diameter because the beam is dispersed by gas molecules. However, in this embodiment, the area of the printed pattern in the substrate to be irradiated with the electron beam is relatively wide, and thus, the larger beam diameter is advantageous, rather than disadvantageous. In addition, in a non-vacuum atmosphere, the electron beam ionizes gas molecules in the atmosphere, such as N₂ and Ar. However, the amount of the ionized gas molecules is quite small, and therefore, there arises no problem.

In the case where such a substrate is disposed out of the vacuum chamber, the electron beam irradiation can be conducted more effectively by filling the space in which the substrate and the window for transmitting the electron beam are disposed with an inert gas, such as helium and argon, or a gas that is less reactive with another material, such as nitrogen.

In addition, in the case where the substrate is disposed out of the vacuum chamber, the efficiency of precipitation of the metal catalyst by electron beam irradiation can be increased by filling the space in which the substrate is disposed with an active gas, such as oxygen, hydrogen and a halogen, that is effective for decomposition of an organic constituent. In this case, if there is a possibility of deterioration of the material of the window for transmitting the electron beam or deposition of a material on the window, in order to avoid such a phenomenon, there can be provided a mechanism that locally supplies an inert gas to produce an inert gas atmosphere around the window.

On the other hand, in the case where the metal catalyst is precipitated from the printed patterned metal compound film to form the patterned metal catalyst film by heating, rather than electron beam irradiation, the printing unit 224 prints the pattern on the base material using the solvent containing the metal compound containing the metal catalyst, and then, the base material is heated by the heating unit 227. By this heating treatment, the patterned metal catalyst film is formed. For example, in the case where a flexible printed circuit board is fabricated by a laser-shot printing unit 224 printing a wiring pattern made of the metal catalyst or a powder containing the metal catalyst on a plastic film or sheet base material, the printing unit 224 prints the pattern on the base material, and then the base material is baked by the heating unit 227. By this baking treatment, the patterned metal catalyst film is formed.

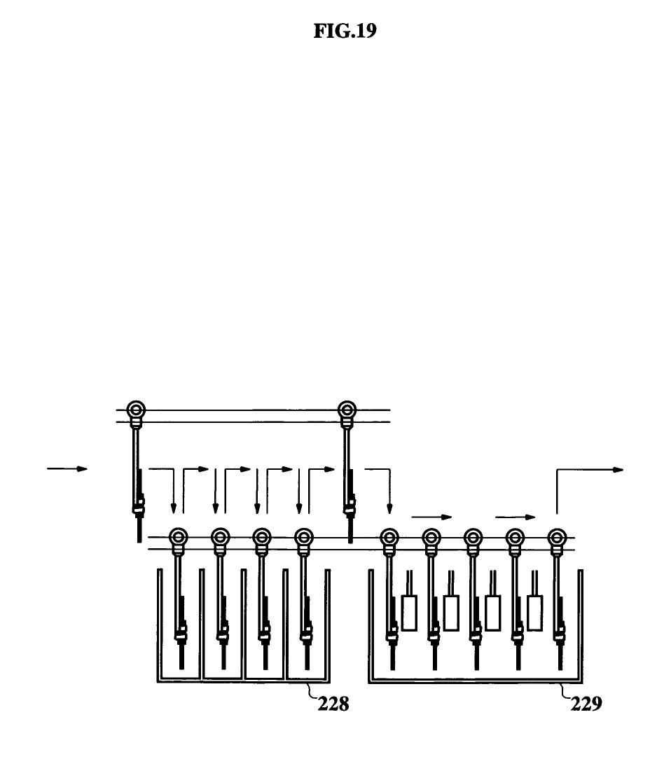

As shown in FIG. 19, after the electron beam irradiation, heating treatment or baking treatment is completed, the base material is fed to the first pre-plating treatment unit 228, where a pre-treatment required before electroless plating of the metal catalyst film with the wiring-forming metal is performed. Specifically, an acid cleaning treatment and an accelerating treatment are performed as the pre-treatment.

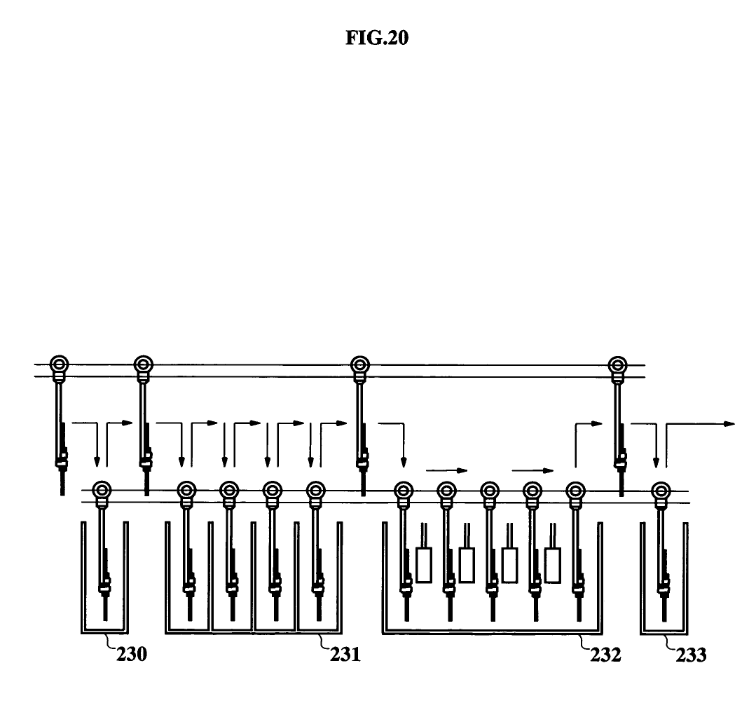

Then, plating of the base material is performed in the electroless-plating unit 229, and as shown in FIG. 20, the base material is treated in the second washing tank 230 and the second pre-plating treatment unit 231. Then, electroplating of the base material is performed in the electroplating unit 232, and thus, the base material is plated with an enough amount of metal to function as the wiring.

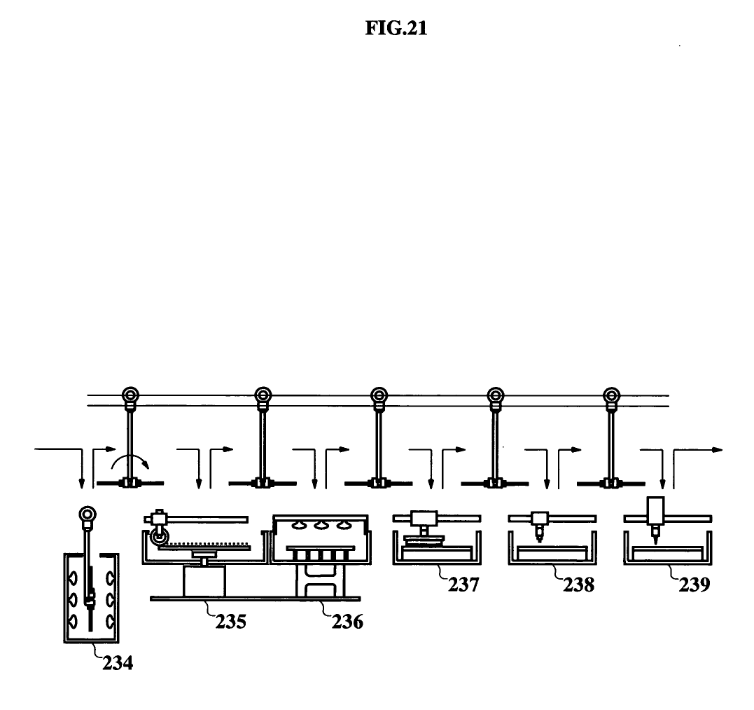

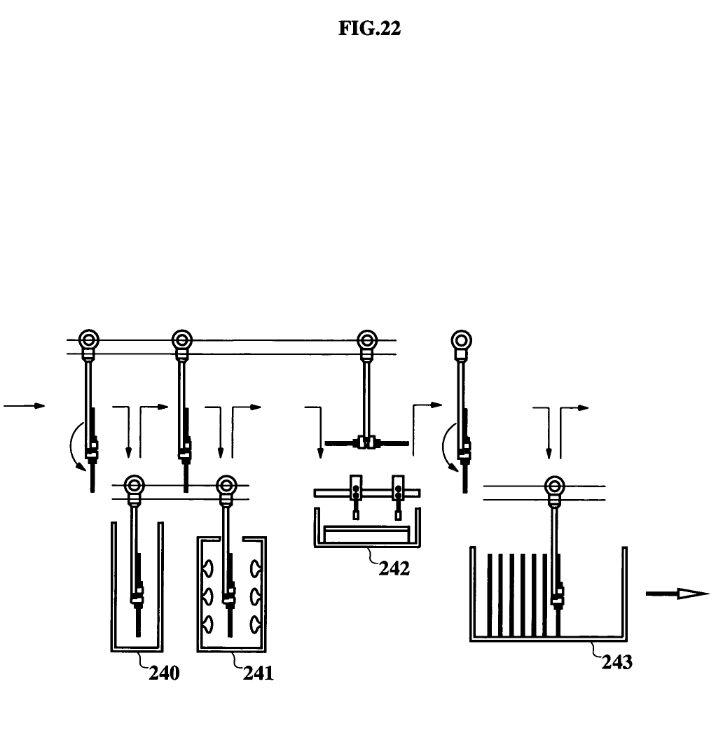

The base material is washed in the third washing tank 233 to complete the procedure of forming one layer of wiring pattern. Then, as shown in FIG. 21, the base material is dried in the third drying unit 234, an insulating film is applied to the base material in the insulating film applying unit 235, and the applied insulating film is cured in the insulating film curing unit 236. As required, the film is planarized with the polisher 237, and a via hole or through hole is formed at a desired location in the base material with the laser processing unit 238. In addition, as required, a hole is formed in the base material with the hole drilling unit 239. Then, as shown in FIG. 22, after the base material is washed in the fourth washing tank 240, the base material is dried in the fourth drying unit 241. Furthermore, the testing unit 242 determines whether the base material is good or defective as a printed circuit board, and the base material is carried out through the outlet 243.

If multiple layers of wiring are required, the base material is fed from the testing unit 242 to the first washing tank 222, and the series of steps are repeated a required number of times. In this case, since wiring patterns of the layers are different from each other, the control unit 143 controlling the patterning apparatus 220 provides information about the wiring pattern of each layer to the solvent printing unit 224. Once the multiple layers of wiring are completed, an insulating film functioning as a protective film is applied to the base material in the insulating film applying unit 235, and the applied insulating film is cured in the insulating film curing unit 236.

As described above, according to the first and second aspects of the present invention, there is provided a wiring plating method that does not need application, lamination and stripping of a resist and etching of a copper foil that would otherwise be required to form a patterned plating wiring on a substrate, such as a printed circuit board, and assures sufficient adhesion of the obtained plating wiring to the substrate. Thus, there is provided a technique that enables simplification of the manufacturing process and reduction of the manufacturing cost.

While the method of fabricating a printed circuit board according to the present invention and the printed circuit board fabricated by the method have been described with reference to embodiments of the present invention, the embodiments described above are intended only for illustrating the present invention, and the present invention is not limited thereto. In particular, the present invention can be applied also to patterning of a metal film on an insulating film on a semiconductor substrate.

It will be apparent from the above description that various modification of the embodiments described above are also included in the scope of the present invention, and various alterations are possible within the scope of the present invention.

What is claimed is:

1. A substrate having a metal film, comprising:
a patterned metal catalyst film formed on an insulating layer formed on a flat plate or a principal surface of an insulating flat base material, the insulating layer and the insulating flat base material being made of a plastic resin capable of being molten, ablated or chemically modified locally in an area that is irradiated with an energy beam; and
a metal wiring formed by plating on the metal catalyst film.

2. The substrate having a metal film according to claim 1, wherein said plastic resin is a resin selected from a group containing polyimide, epoxy, bismaleimide triazine (BT resin), polyphenylene ether, polyacetal and phenol or a fiber reinforced plastic resin that contains a resin selected from said group.

3. The substrate having a metal film according to claim 1, wherein said metal catalyst film contains at least one compound selected from a group containing a metal carboxylate, a nitrate compound, a chloride, an iodine compound, a hydroxide, a fluorine compound, a sulfate compound, a sulfur compound, and a compound of a chelate compound and an organic compound.

4. The substrate having a metal film according to claim 1, wherein an adhesive made of a material that is the same as or highly compatible with the material of the insulating layer or insulating flat base material is provided on a surface of the insulating layer or insulating flat base material.

5. A substrate having a metal film, comprising:
a patterned metal catalyst film formed on an insulating layer formed on a flat plate or a principal surface of an insulating flat base material, the metal compound or granular metal in the metal catalyst film serving as the plating catalyst for metal wiring being dispersed or mixed in at least one of a liquid binder and a granular binder that are the same material as or highly compatible with said insulating layer or insulating flat base material and are capable of being made adhesive to a surface of said insulating layer or insulating flat base material by irradiation with an energy beam; and
a metal wiring formed by plating on the metal catalyst film.

6. The substrate having a metal film according to claim 5, wherein the average diameter of said granular binder is equal to or more than 0.1 μm and equal to or less than 10 μM.

7. The substrate having a metal film according to claim 5, wherein said metal catalyst film is a film containing at least one compound selected from a group containing a metal carboxylate, a nitrate compound, a chlorides, iodine compounds, hydroxides, fluorine compounds, sulfate compound, a sulfur compound, and a compound of a chelate compound and an organic compound.

8. The substrate having a metal film according to claim 5, wherein said metal compound or granular metal is a metal selected from a group containing Pd, Au, Pt, Ag, In, Co and Sn or an alloy of at least two metals selected from the group.

9. The substrate having a metal film according to claim 5, wherein an adhesive made of a material that is the same as or highly compatible with the material of the insulating layer or insulating flat base material is provided on a surface of the insulating layer or insulating flat base material.

10. A method of forming a metal film, comprising:
a first step of forming a film containing a metal compound containing a first metal on an insulating layer formed on a flat plate or a principal surface of an insulating flat base material by applying a metal compound film containing the first metal to said insulating layer or the principal surface of said insulating flat base material;
a second step of irradiating said film containing the metal compound containing the first metal with an energy beam, thereby precipitating the first metal from said film containing the metal compound containing the first metal and locally melting, ablating or chemically modifying the area of said insulating layer or said insulating flat base material that is irradiated with the energy beam; and
a third step of, using said precipitated first metal as a catalyst layer, plating the surface of said catalyst layer with a second metal using a plating solution containing the second metal, thereby forming a second metal film.

11. The method of forming a metal film according to claim 10, further comprising:
a step of applying an adhesive made of a material that is the same as or highly compatible with the insulating layer or insulating flat base material to said insulating layer or the principal surface of the insulating flat base material before said first step,
wherein said first step is performed after said applied adhesive is cured or partially cured.

12. The method of forming a metal film according to claim 10, wherein the formation of the film containing the metal compound containing the first metal in said first step is performed by applying a solvent containing the metal compound containing the first metal to said insulating layer or the principal surface of the insulating flat base material and drying the solvent.

13. The method of forming a metal film according to claim 10, wherein said second step includes a sub-step of removing said film containing the metal compound containing the first metal in the area that is not irradiated with the energy beam after the irradiation with the energy beam.

14. The method of forming a metal film according to claim 10, wherein said metal compound is an organic metal compound, and the irradiation with the energy beam is conducted in a vacuum, an atmosphere of an inert gas, or an atmosphere of a reducing gas.

15. The method of forming a metal film according to claim 10, wherein said second step includes a sub-step of performing a heat treatment after said first metal is precipitated.

16. A method of forming a metal film, comprising:
a first step of forming a film containing a metal compound containing a first metal on an insulating layer formed on a flat plate or a principal surface of an insulating flat base material by applying a metal compound film containing the first metal to said insulating layer or the principal surface of said insulating flat base material, the metal compound containing the first metal forming the film being a metal compound or granular metal for serving as a plating catalyst for a second metal that is dispersed or mixed in at least one of a liquid binder and a granular binder that are the same material as or highly compatible with said insulating layer or insulating flat base material; and
a second step of irradiating said film containing the metal compound containing the first metal with an energy beam under a condition that said binder is physically or chemically changed to adhere the surface of said insulating layer or insulating flat base material, thereby precipitating said first metal from the film containing the metal compound containing the first metal; and
a third step of, using said precipitated first metal as a catalyst layer, plating the surface of said catalyst layer with the second metal using a plating solution containing the second metal, thereby forming a second metal film.

17. The method of forming a metal film according to claim 16, further comprising:
a step of applying an adhesive made of a material that is the same as or highly compatible with the insulating layer or insulating flat base material to said insulating layer or the principal surface of the insulating flat base material before said first step,
wherein said first step is performed after said applied adhesive is cured or partially cured.

18. The method of forming a metal film according to claim 16, wherein the formation of the film containing the metal compound containing the first metal in said first step is performed by applying a solvent containing the metal compound containing the first metal to said insulating layer or the principal surface of the insulating flat base material and drying the solvent.

19. The method of forming a metal film according to claim 16, wherein said second step includes a sub-step of removing said film containing the metal compound containing the first metal in the area that is not irradiated with the energy beam after the irradiation with the energy beam.

20. The method of forming a metal film according to claim 16, wherein said metal compound is an organic metal compound, and the irradiation with the energy beam is conducted in a vacuum, an atmosphere of an inert gas, or an atmosphere of a reducing gas.

21. The method of forming a metal film according to claim 16, wherein said second step includes a sub-step of performing a heat treatment after said first metal is precipitated.

22. A method of patterning a metal film, comprising:
a first step of printing a desired pattern of a metal compound film containing a first metal on an insulating layer or principal surface of an insulating base material, thereby forming a film containing the metal compound containing the first metal on the principal surface of said insulating base material;
a second step of irradiating the film containing the metal compound containing the first metal with an energy beam, thereby precipitating the first metal from the film containing the metal compound containing the first metal and locally melting, ablating or chemically modifying the area of said insulating base material that is irradiated with the energy beam; and
a third step of, using said precipitated first metal as a catalyst, plating the surface of the catalyst layer with a second metal.

23. The method of patterning a metal film according to claim 22, wherein the film containing the metal compound containing the first metal is a film containing at least one compound selected from a group containing a metal carboxylate, a nitrate compound, a chloride, an iodine compound, a hydroxide, a fluorine compound, a sulfate compound, and a compound of a chelate compound and an organic compound.

24. The method of patterning a metal film according to claim 22, wherein said first metal is a metal selected from a group containing Pd, Au, Pt, Ag, In, Co and Sn or an alloy of at least two metals selected from the group.

25. The method of patterning a metal film according to claim 22, wherein the pattern printing of the metal compound in said first step is performed by laser shot printing using a powder of said first metal or ink jet printing or micro-contact printing using a solvent containing the metal compound containing the first metal as an ink material.

26. The method of patterning a metal film according to claim 25, wherein said solvent contains at least one of a liquid binder and a granular binder that are the same material as or highly compatible with said insulating layer or insulating base material.

27. The method of patterning a metal film according to claim 25, wherein said powder is mixed with or contains a granular binder that is the same material as or highly compatible with said insulating layer or insulating base material.

28. A method of patterning a metal film, comprising:
a first step of printing a desired pattern of a metal compound film containing a first metal on an insulating layer or principal surface of an insulating base material, thereby forming a film containing the metal compound containing the first metal on the principal surface of said insulating base material, the metal compound containing the first metal forming the film being a metal compound or granular metal for serving as a plating catalyst for a second metal that is dispersed or mixed in at least one of a liquid binder and a granular binder that are the same material as or highly compatible with said insulating flat base material;
a second step of performing energy beam irradiation or heat treatment of said film containing the metal compound containing the first metal under a condition that said binder is physically or chemically changed to adhere the surface of said insulating base material, thereby precipitating said first metal from the film containing the metal compound containing the first metal from the film containing the metal compound containing the first metal; and
a third step of, using said precipitated first metal as a catalyst layer, plating the surface of the catalyst layer with the second metal.

29. The method of patterning a metal film according to claim 28, wherein the film containing the metal compound containing the first metal is a film containing at least one compound selected from a group containing a metal carboxylate, a nitrate compound, a chloride, an iodine compound, a hydroxide, a fluorine compound, a sulfate compound, and a compound of a chelate compound and an organic compound.

30. The method of patterning a metal film according to claim 28, wherein said first metal is a metal selected from a group containing Pd, Au, Pt, Ag, In, Co and Sn or an alloy of at least two metals selected from the group.

31. The method of patterning a metal film according to claim 28, wherein the pattern printing of the metal compound in said first step is performed by laser shot printing using a powder of said first metal or ink jet printing or micro-contact printing using a solvent containing the metal compound containing the first metal as an ink material.

32. The method of patterning a metal film according to claim 31, wherein said solvent contains at least one of a liquid binder and a granular binder that are the same material as or highly compatible with said insulating layer or insulating base material.

33. The method of patterning a metal film according to claim 31, wherein said powder is mixed with or contains a granular binder that is the same material as or highly compatible with said insulating layer or insulating base material.

34. A substrate fabricating apparatus, comprising:
a carrier unit that has a holding table for holding a flat plate and an arm for carrying said flat plate;
an applying unit that applies a metal compound containing a first metal to an insulating layer on said flat plate;
an energy beam irradiation unit that irradiates said applied metal compound containing the first metal with an energy beam in a predetermined pattern;
a washing unit that washes the surface of the insulating layer on said flat plate irradiated with said energy beam;
a metal plating unit that plates said washed insulating layer on the flat plate with a second metal;
an insulating film applying unit that applies an insulating film on said flat plate;
an insulating film curing unit that cures said insulating film; and
a hole forming unit that forms at least one of a via hole and a through hole,
wherein said carrier unit is controlled by a controller so as to sequentially carry said flat plate from said applying unit to said energy beam irradiation unit, from the energy beam irradiation unit to said washing unit, from the washing unit to said metal plating unit, from the metal plating unit to said insulating film applying unit, from the insulating film applying unit to said insulating film curing unit, and from the insulating film curing unit to said hole forming unit.

35. A substrate fabricating system, comprising a substrate fabricating apparatus as set forth in claim 34 and a host computer capable of collectively managing the substrate fabricating process, which are connected to each other via a network.
